(19) United States
(12) Patent Application Publication
(10) Pub. No.: US 2026/0276597 A1
(43) Pub. Date: Sep. 17, 2026

(54) INSPECTION APPARATUS, INSPECTION METHOD, AND METHOD FOR MANUFACTURING SEMICONDUCTOR DEVICE

(71) Applicant: Kioxia Corporation, Tokyo (JP)

(72) Inventors: Yoshio MIZUTA, Yokkaichi Mie (JP); Hikaru TAKAYANAGI, Yokkaichi Mie (JP)

(73) Assignee: Kioxia Corporation, Tokyo (JP)

(21) Appl. No.: 19/234,665

(22) Filed: Jun. 11, 2025

(30) Foreign Application Priority Data
Mar. 14, 2025 (JP) 2025-040823

(51) Int. Cl. G01N 29/07; G01N 29/24; H10P 74/20

(52) U.S. Cl. CPC G01N 29/07; G01N 29/2437; H10P 74/203; G01N 2291/011; G01N 2291/0231; G01N 2291/0289; G01N 2291/101

(57) ABSTRACT

According to an inspection apparatus of an embodiment, a processor: causes a probe to emit a first ultrasonic wave from a second surface side to a reference point of a substrate; causes the probe to receive a first reflected wave reflected at the reference point; estimates a first time required for reception of a reflected wave reflected by a first cavity defect based on a time from when the first ultrasonic wave is emitted to when the first reflected wave is received, and sets a first detection period based on the first time; and estimates a second time required for reception of a reflected wave reflected by a second cavity defect based on a time from when the first ultrasonic wave is emitted to when the first reflected wave is received, and sets a second detection period based on the second time.

### CROSS-REFERENCE TO RELATED APPLICATIONS

This application is based upon and claims the benefit of priority from Japanese Patent Application No. 2025-040823, filed on Mar. 14, 2025; the entire contents of which are incorporated herein by reference.

### FIELD

Embodiments described herein relate generally to an inspection apparatus, an inspection method, and a method for manufacturing a semiconductor device.

### BACKGROUND

There is an inspection method of detecting a cavity defect in a structure by irradiating a substrate on which the structure is formed with an ultrasonic wave. In the structure, a plurality of cavity defects may be included at different depth positions. It is desirable to specify depth positions of these cavity defects with high accuracy to improve inspection accuracy for the cavity defects.

### BRIEF DESCRIPTION OF THE DRAWINGS

FIG. 1 is a cross-sectional view illustrating a schematic configuration example of a semiconductor device according to an embodiment;

FIGS. 2A and 2B are cross-sectional views sequentially exemplifying a part of a procedure of a method for manufacturing the semiconductor device according to the embodiment;

FIG. 3 is a cross-sectional view sequentially exemplifying a part of the procedure of the method for manufacturing the semiconductor device according to the embodiment;

FIGS. 4A to 4C are cross-sectional views sequentially exemplifying a part of the procedure of the method for manufacturing the semiconductor device according to the embodiment;

FIG. 5 is a schematic diagram illustrating an example of a configuration of an inspection apparatus according to the embodiment;

FIGS. 6A to 6C are schematic diagrams illustrating an inspection method for the semiconductor device by the inspection apparatus according to the embodiment;

FIGS. 7A and 7B are schematic graphs illustrating an example of an inspection result for the semiconductor device obtained by the inspection apparatus according to the embodiment;

FIGS. 8A to 8C are schematic graphs illustrating an example of an inspection result for the semiconductor device obtained by an inspection apparatus according to a comparative example;

FIGS. 9A and 9B are diagrams sequentially exemplifying a part of a method for manufacturing the semiconductor device according to a first modification of the embodiment;

FIG. 10 is a diagram sequentially exemplifying a part of the method for manufacturing the semiconductor device according to the first modification of the embodiment;

FIGS. 11A to 11C are diagrams sequentially exemplifying a part of a method for manufacturing the semiconductor device according to a second modification of the embodiment;

FIGS. 12A and 12B are diagrams sequentially exemplifying a part of the method for manufacturing the semiconductor device according to the second modification of the embodiment;

FIGS. 13A and 13B are cross-sectional views sequentially exemplifying a part of a method for manufacturing the semiconductor device according to a third modification of the embodiment;

FIG. 14 is a cross-sectional view sequentially exemplifying a part of the method for manufacturing the semiconductor device according to the third modification of the embodiment; and

FIGS. 15A and 15B are schematic graphs illustrating an example of an inspection result for the semiconductor device obtained by an inspection method according to the third modification of the embodiment.

### DETAILED DESCRIPTION

An inspection apparatus of an embodiment is an inspection apparatus that detects a cavity defect in a structure by emitting an ultrasonic wave to a substrate including the structure on a first surface, the inspection apparatus including: a probe that transmits and receives the ultrasonic wave; and a processor that analyzes a reflected wave received by the probe, in which the cavity defect includes at least any of: a first cavity defect located at a first distance from a second surface on an opposite side from the first surface; and a second cavity defect located at a second distance from the second surface, the second distance being larger than the first distance, and the processor: causes the probe to emit a first ultrasonic wave from a second surface side to a reference point; causes the probe to receive a first reflected wave reflected at the reference point; estimates a first time required for reception of a reflected wave reflected by the first cavity defect based on a time from when the first ultrasonic wave is emitted to when the first reflected wave is received, and sets a first detection period based on the first time; and estimates a second time required for reception of a reflected wave reflected by the second cavity defect based on a time from when the first ultrasonic wave is emitted to when the first reflected wave is received, and sets a second detection period based on the second time.

Hereinafter, embodiments of the present invention will be described in detail with reference to the drawings. Note that the present invention is not limited by the following embodiments. In addition, constituent elements in the following embodiments include those that can be easily assumed by those skilled in the art or those that are substantially the same.

### Configuration Example of Semiconductor Device

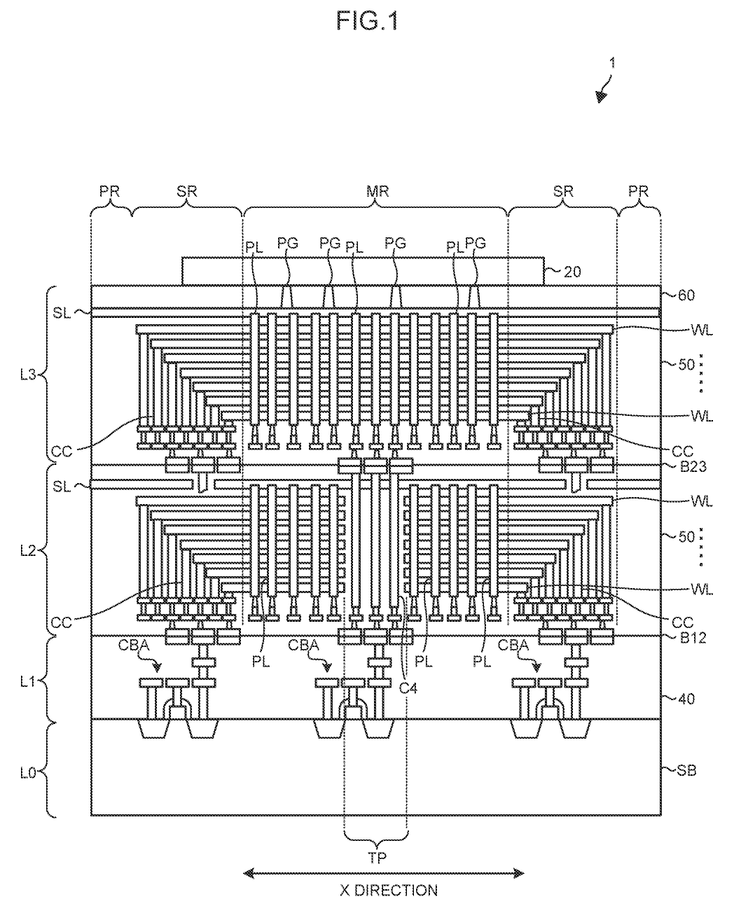

FIG. 1 is a cross-sectional view illustrating a schematic configuration example of a semiconductor device 1 according to an embodiment. However, hatching is omitted in FIG. 1 in consideration of visibility of the drawing. In addition, in FIG. 1, some upper layer wiring lines and the like are omitted.

As illustrated in FIG. 1, the semiconductor device 1 includes layers L0 to L3 in order from the lower side of the drawing. Among these layers L0 to L3, the layers L1 to L3 are bonded to each other. The layer L1 and the layer L2 are bonded together through a bonding surface B12, and the layer L2 and the layer L3 are bonded together through a bonding surface B23.

In addition, the layer L0 includes a semiconductor substrate SB. The layer L1 includes peripheral circuits CBA each including a transistor TR and the like. Each of the layers L2 and L3 includes a plurality of word lines WL, pillars PL penetrating therethrough, and the like.

More specifically, the peripheral circuits CBA belonging to the layer L1 and each including the transistor TR, wiring lines, and the like are disposed on the front surface of the semiconductor substrate SB belonging to the layer L0, and the whole thereof is covered with the insulating layer 40. Above the semiconductor substrate SB on which the peripheral circuits CBA and the like are disposed, each of sets of the plurality of word lines WL is disposed, the sets respectively belonging to the layer L2 and L3 and each being entirely covered with an insulating layer 50.

A memory region MR is disposed at a central portion in the X direction of each of sets of the plurality of word lines WL respectively belonging to the layers L2 and L3, and a staircase region SR is disposed at each of both end portions in the X direction of the plurality of word lines WL. A peripheral region PR is disposed outside the plurality of word lines WL in the X direction. The insulating layer 50 covering the plurality of word lines WL extends to the peripheral region PR. In addition, a through region TP is disposed in a central portion of the memory region MR of the plurality of word lines WL belonging to the layer L2 of the layers L2 and L3.

In the memory region MR, the plurality of pillars PL is disposed. The plurality of pillars PL penetrates the plurality of word lines WL and reaches a source line SL disposed at an upper end portion of each of the layers L2 and L3. A plurality of memory cells is formed at intersections of the pillars PL and the word lines WL.

As a result, the semiconductor device 1 is configured as, for example, a three-dimensional nonvolatile memory in which the memory cells are three-dimensionally disposed in the memory region MR.

In the staircase region SR, the plurality of word lines WL is processed in a staircase shape and terminated. Contacts CC extending upward in the insulating layer 50 and connected to the word lines WL of each layer are respectively disposed in terrace portions of steps formed by the plurality of word lines WL processed in the staircase shape.

The word lines WL stacked in multiple layers are individually drawn out by these contacts CC. More specifically, write voltages, read voltages, and the like are applied from these contacts CC to the memory cells included in the memory region MR in the central portion of the plurality of word lines WL via the word lines WL at the same height positions as the memory cells.

A plurality of through contacts C4 penetrating the plurality of word lines WL belonging to the layer L2 is disposed in the through region TP of the layer L2.

Here, the peripheral circuits CBA of the layer L1, and the contacts CC and the pillars PL of the layer L2 are electrically connected to each other through electrode pads disposed on the bonding surface B12, and the like. In addition, the peripheral circuits CBA of the layer L1, and the contacts CC and the pillars PL of the layer L3 are electrically connected to each other through electrode pads disposed on the bonding surface B23, the through contacts C4 of the layer L2, and the like.

As a result, application of a predetermined voltage from the contacts CC to the memory cells is controlled by the peripheral circuits CBA electrically connected to these contacts CC. In addition, data held by each memory cell of the pillars PL is read out to the peripheral circuits CBA electrically connected to these pillars PL. As described above, the peripheral circuits CBA control electrical operation of the memory cells.

In addition, an electrode film EL is disposed further above the layer L3 with an insulating layer 60 interposed therebetween. The electrode film EL is connected to the source line SL by plugs PG penetrating the insulating layer 60, and the like. From the electrode film EL, a power supply and a signal from the outside are supplied to the semiconductor device 1.

### Method for Manufacturing Semiconductor Device

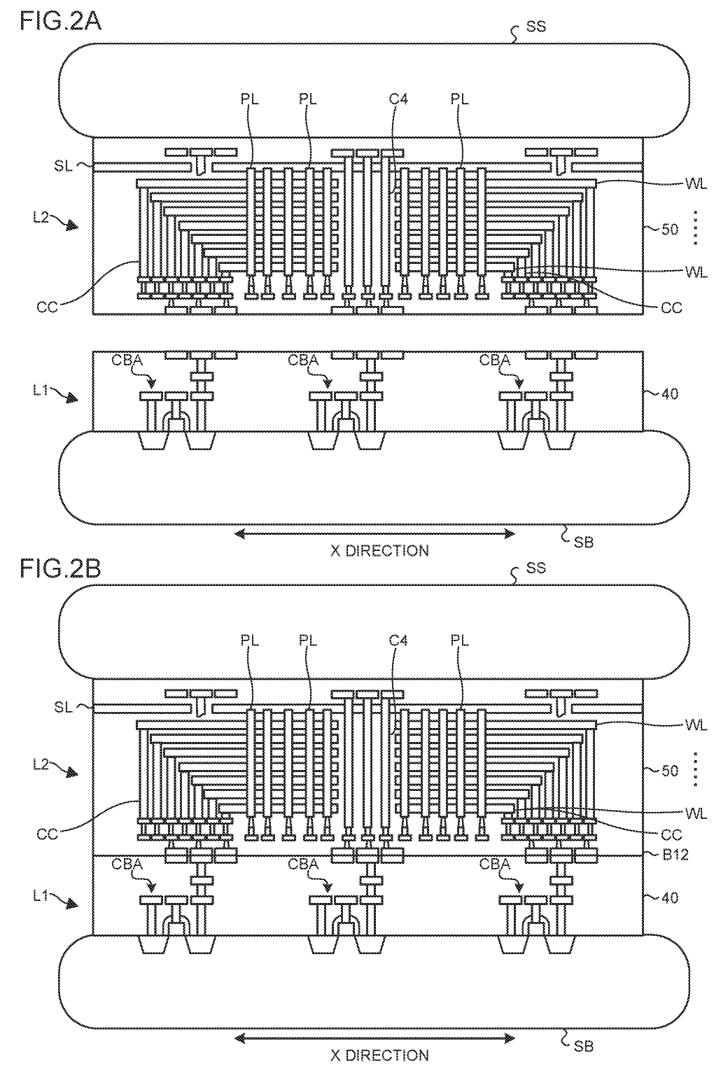

Next, with reference to FIGS. 2A to 4C, a description will be given of a method for manufacturing the semiconductor device 1 of the embodiment. FIGS. 2A to 4C are cross-sectional views sequentially exemplifying a part of a procedure of the method for manufacturing the semiconductor device 1 according to the embodiment.

As illustrated in FIG. 2A, each of configurations of the layer L1 is formed on the semiconductor substrate SB. That is, the peripheral circuits CBA each including the transistor TR, wiring lines, and the like are formed on the semiconductor substrate SB, the whole thereof is covered with the insulating layer 40, and a plurality of electrode pads is formed on the front surface.

In addition, each of configurations of the layer L2 is formed on a support substrate SS such as a semiconductor substrate. That is, the source line SL and the plurality of word lines WL are formed in this order on the support substrate SS with the insulating layer 50 including the plurality of electrode pads interposed therebetween, and both end portions in the X direction of the plurality of word lines WL are processed in a staircase shape. In addition, the plurality of pillars PL penetrating the word lines WL to reach the source line SL is formed, and the plurality of contacts CC is formed at staircase portions at both end portions in the X direction of the plurality of word lines WL. In addition, the plurality of through contacts C4 penetrating the word lines WL to reach the electrode pads are formed, the whole thereof is further covered with the insulating layer 50, and a plurality of electrode pads is formed on the front surface.

Note that, although only the configuration included in the layer L2 for one semiconductor device 1 is illustrated in FIG. 2A, a number of the configurations included in the layer L2 are formed on one support substrate SS, the number corresponding to a plurality of the semiconductor devices 1.

In addition, the semiconductor substrate SB and the support substrate SS are disposed such that the insulating layer 40 covering the peripheral circuits CBA and the like faces the insulating layer 50 covering the plurality of word lines WL and the like.

As illustrated in FIG. 2B, the support substrate SS and the semiconductor substrate SB are bonded together with their respective insulating layers 50 and 40, and the electrode pads in the insulating layers 50 and 40 are connected together. These insulating layers 50 and 40 can be bonded together by being activated in advance by, for example, plasma treatment or the like.

As a result of the above, the bonding surface B12 is formed at the interface between the insulating layers 40 and 50.

However, at this time point, these insulating layers 50 and 40 are in a temporarily bonded state, and bonding strength between the insulating layers 50 and 40 is not sufficiently high.

By performing annealing treatment after the insulating layers 50 and 40 are bonded together in this manner, it is possible to connect the electrode pads in the insulating layers 50 and 40 together by Cu-Cu bonding or the like, and sufficiently increase the bonding strength between the insulating layers 50 and 40.

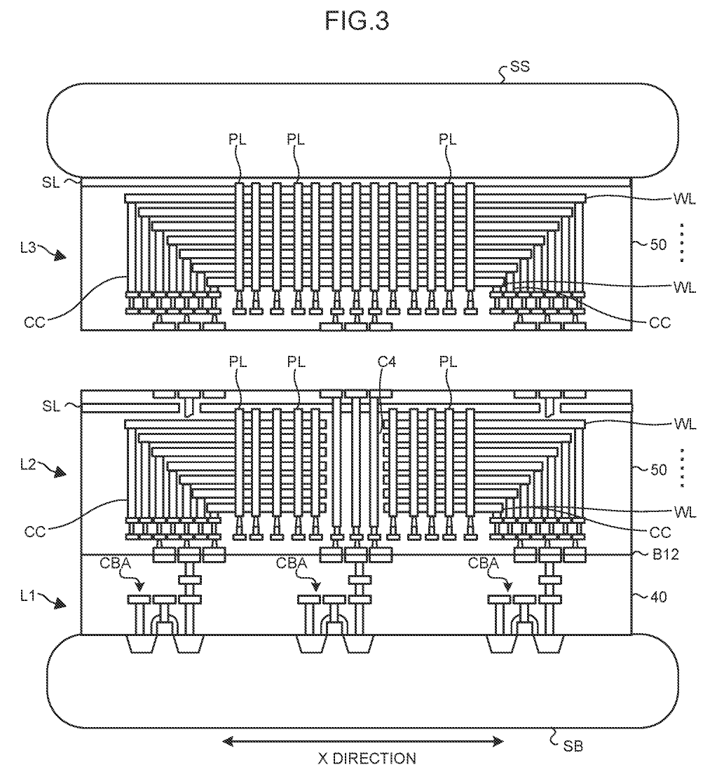

As illustrated in FIG. 3, the support substrate SS that is vertically inverted and bonded to the semiconductor substrate SB is removed by grinding or the like to expose the plurality of electrode pads included in the insulating layer 50 between the support substrate SS and the source line SL.

In addition, the support substrate SS such as a semiconductor substrate is newly prepared, and each of configurations of the layer L3 is formed on the support substrate SS. That is, the source line SL and the plurality of word lines WL are formed in this order on the new support substrate SS, and both end portions in the X direction of the plurality of word lines WL are processed in a staircase shape. In addition, the plurality of pillars PL penetrating the word lines WL to reach the source line SL is formed, the plurality of contacts CC is formed at staircase portions at both end portions in the X direction of the plurality of word lines WL, the whole thereof is covered with the insulating layer 50, and the plurality of electrode pads is formed on the front surface.

Note that, although only the configuration included in the layer L3 for one semiconductor device 1 is illustrated in FIG. 3, a number of the configurations included in the layer L3 are formed on one support substrate SS, the number corresponding to the plurality of semiconductor devices 1.

In addition, the semiconductor substrate SB and the support substrate SS are disposed such that the insulating layer 50 bonded to the semiconductor substrate SB and including the electrode pads exposed on the front surface thereof faces the insulating layer 50 covering the plurality of word lines WL and the like belonging to the layer 3 on the support substrate SS.

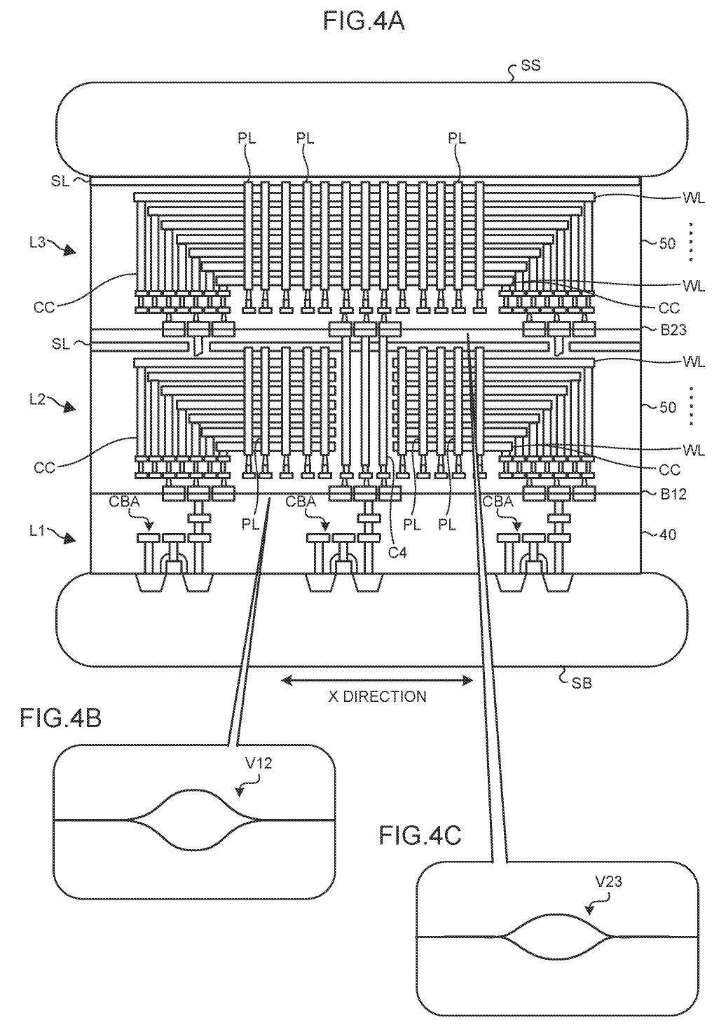

As illustrated in FIG. 4A, the support substrate SS on which the layer L3 is formed and the semiconductor substrate SB on which the layer L2 is bonded above the peripheral circuits CBA are bonded together with the insulating layers 50 and 50 respectively included therein, and the electrode pads in the insulating layers 50 and 50 are connected together. These insulating layers 50 and 50 can also be bonded together by being activated in advance by, for example, plasma treatment or the like. As a result, the bonding surface B23 is formed at the interface between the insulating layers 50 and 50.

In addition, after the insulating layers 50 and 50 are temporarily bonded together as described above, annealing treatment is performed, whereby the electrode pads in the insulating layers 50 and 50 are connected together by Cu-Cu bonding or the like, and the bonding strength of these insulating layers 50 and 50 is strengthened.

Thereafter, the support substrate SS is removed by grinding or the like, and a configuration in which the configurations for the plurality of semiconductor devices 1 are formed in the individual layers L1 to L3 is singulated for each of the configurations, whereby the semiconductor device 1 of the embodiment is manufactured.

Here, when the insulating layers 40 and 50 are bonded together or the insulating layers 50 and 50 are bonded together, an atmosphere at the time of bonding may be trapped in each of the bonding surfaces B12 and B23 to generate a cavity.

In a case where the cavity is very large, there is a case where separation of an upper layer portion occurs at the time of grinding and removing the support substrate SS. In addition, even if the size of the cavity is medium, the trapped atmosphere may expand in a subsequent process, and the cavity portion may burst. Thus, at the time of bonding together the insulating layers 40 and 50 illustrated in FIG. 2B and at the time of bonding together the insulating layers 50 and 50 illustrated in FIG. 4A, the presence or absence of a cavity defect in each of the bonding surfaces B12 and B23 is inspected by use of an ultrasonic wave or the like. More specifically, a cavity defect inspection is performed at a time point at which the insulating layers 40 and 50 illustrated in FIG. 2B or the insulating layers 50 and 50 illustrated in FIG. 4A are temporarily bonded together before the layers are more firmly bonded together by the annealing treatment.

In a case where a cavity defect is detected in such an inspection and the cavity has a size greater than or equal to a predetermined size, separation of a bonded portion is performed, and re-bonding is performed to the same semiconductor substrate SB or to a different semiconductor substrate SB. At this time, in re-bonding, a bonding surface may be re-polished. As described above, at a time point of the cavity defect inspection, since these insulating layers are in a temporarily bonded state, separation of the bonded portion can be easily performed, and re-bonding can be performed as necessary.

In a case where the cavity has a size less than the predetermined size, it is considered that there is a low possibility that separation of the cavity upper layer portion, bursting of the cavity portion, or the like occurs, and the subsequent process is continued while the cavity defect is included. However, the semiconductor device 1 obtained from a portion overlapping with the cavity is treated as a defective product.

At this time, in a case where the bonding surface B12 that is the first bonding surface includes a cavity defect having a size less than the predetermined size, when inspection is performed of the cavity defect on the bonding surface B23 that is the subsequent bonding surface, it is desirable to distinguish whether a detected cavity defect is generated in the bonding surface B12 or the bonding surface B23 with high accuracy. This is because it is possible to determine whether or not re-bonding at this stage is necessary with high accuracy by distinguishing only a cavity generated in the bonding surface B23.

As illustrated in FIGS. 4B and 4C, hereinafter, among cavity defects generated in the bonding surfaces B12 and B23 of the semiconductor device 1, a cavity defect generated in the bonding surface B12 that is the first bonding surface is referred to as a cavity defect V12, and a cavity defect generated in the bonding surface B23 that is the subsequent bonding surface is referred to as a cavity defect V23.

### Configuration Example of Inspection Apparatus

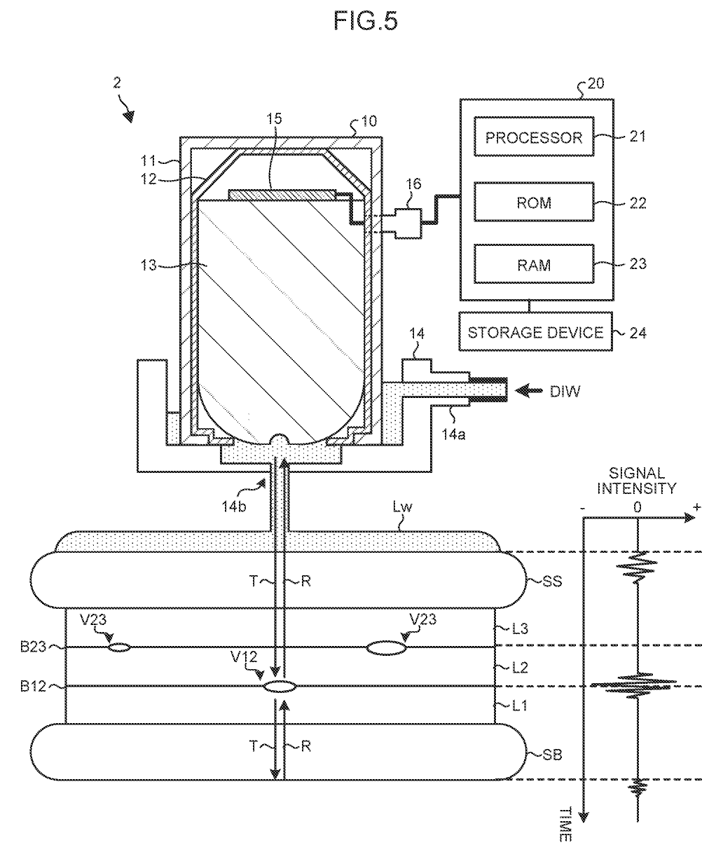

Next, with reference to FIG. 5, a description will be given of a configuration example of an inspection apparatus 2 used for detection of the cavity defects V12 and V23 in the semiconductor device 1 of the embodiment. FIG. 5 is a schematic diagram illustrating an example of a configuration of the inspection apparatus 2 according to the embodiment.

As illustrated in FIG. 5, the inspection apparatus 2 of the embodiment includes a probe 10 and a computer 20.

The probe 10 includes cases 11 and 12, a housing 13, a water basin 14, a vibrator 15, and a connector 16.

The housing 13 has a cavity inside, and is accommodated in the cases 11 and 12 having a double structure of the outside and the inside. The vibrator 15 is disposed on the upper surface of the housing 13. The vibrator 15 is, for example, a piezoelectric element or the like, and generates an ultrasonic wave by application of a predetermined voltage, and generates a voltage by application of physical force such as an ultrasonic wave.

The cases 11 and 12 in which the housing 13 is accommodated together with the vibrator 15 are installed on the water basin 14. The water basin 14 includes an introduction port 14a for pure water (De-ionized water (DIW)) on the side surface, and an outflow port 14b for the pure water on the lower surface.

The computer 20 includes a processor 21, a read only memory (ROM) 22, a random access memory (RAM) 23, and a storage device 24.

The processor 21 controls the entire inspection apparatus 2. The ROM 22 functions as a storage area in the inspection apparatus 2. Information stored in the ROM 22 is held even when a power supply of the inspection apparatus 2 is turned off. The RAM 23 functions as a primary storage device and serves as a work area of the processor 21. The storage device 24 is an external device such as a hard disk drive (HDD) or a solid state drive (SSD), and functions as an auxiliary storage device of the processor 21.

Note that the inspection apparatus 2 may include an input/output device (not illustrated) such as a keyboard, a mouse, and a display. The input/output device is configured to enable a user to input information, a command, and the like to the inspection apparatus 2 and receive presentation of information from the inspection apparatus 2 as a human machine interface (HMI) between the inspection apparatus 2 and the user.

In addition, a control program executed by the processor 21 is stored in the ROM 22 or the like of the inspection apparatus 2. The control program can be provided by being recorded in various computer-readable recording media such as a flexible disk, a compact disc-recordable (CD-R), a digital versatile disk (DVD), a Blu-ray Disc (registered trademark), and a semiconductor memory.

In addition, the control program may be stored on a computer connected to a network such as the Internet and provided by being downloaded via the network. In addition, the control program may be provided or distributed via a network such as the Internet.

The processor 21 of the inspection apparatus 2 deploys the control program stored in the ROM 22 or the like in the RAM 23 and executes the control program, so that functions are implemented of the inspection apparatus 2 that detects the cavity defects V12 and V23 in the semiconductor device 1, for example. However, some or all of the functions of the inspection apparatus 2 may be implemented by a dedicated application specific integrated circuit (ASIC).

For example, in a case where the cavity defects V12 and V23 in the semiconductor device 1 are inspected by use of such an inspection apparatus 2, pure water is introduced from the introduction port 14a of the water basin 14 and is caused to flow out from the outflow port 14b to the lower side from the water basin 14. The pure water flowing out from the water basin 14 reaches the semiconductor device 1 in the middle of manufacturing disposed below the probe 10, and a liquid film Lw of the pure water is formed on the upper surface of the semiconductor device 1.

Note that, in the example of FIG. 5, a case is illustrated where the semiconductor device 1 in the middle of manufacturing is set as an inspection target, in which the semiconductor device 1 is in a state where both the first bonding and the second bonding are completed. That is, the semiconductor device 1 illustrated in FIG. 5 has a configuration in which the layers L1 to L3 are sandwiched between the semiconductor substrate SB located below and the support substrate SS located above. Thus, in this case, the liquid film Lw of the pure water flowing out from the water basin 14 is formed on the support substrate SS that is the upper surface of the semiconductor device 1.

In a state as described above, a predetermined voltage is applied to the vibrator 15 to generate an ultrasonic wave T. The ultrasonic wave T generated from the vibrator 15 is emitted to the semiconductor device 1 through the inside of the housing 13, the pure water flowing out downward from the water basin 14, and the liquid film Lw of the pure water on the support substrate SS.

At this time, at the interface between the liquid film Lw of pure water and the support substrate SS, the ultrasonic wave T passes from the liquid phase to the solid phase, so that a reflected wave R is generated that is relatively strong. Similarly, on the back surface of the semiconductor substrate SB, the ultrasonic wave T having passed through the semiconductor device 1 passes from the solid phase to the gas phase outside the semiconductor substrate SB, so that the reflected wave R is generated that is relatively strong.

In addition, as in the example of FIG. 5, in the semiconductor device 1, in a case where the cavity defect V12 or the like is present in a path of the ultrasonic wave T, the ultrasonic wave T passes from the solid phase to the gas phase also here, and the reflected wave R is generated that is relatively strong.

The reflected wave R generated by reflection of the ultrasonic wave T at a predetermined interface or the like as described above passes through the support substrate SS that is the upper surface of the semiconductor device 1, the liquid film Lw on the support substrate SS, the pure water flowing out from the water basin 14, and the housing 13 of the probe 10 and is received by the vibrator 15. The processor 21 analyzes the reflected wave R received by the probe 10 and determines whether or not a cavity defect is generated in the semiconductor device 1.

More specifically, the reflected waves R respectively generated at the interface between the liquid film Lw of pure water and the support substrate SS, the interface between the insulating layer 50 of the layer L2 and the cavity defect V12 on the bonding surface B12, and the interface between the semiconductor substrate SB and the atmosphere outside the semiconductor substrate SB are analyzed by the processor 21, and are expressed as, for example, a graph on the right side of the drawing of FIG. 5 illustrated side by side with the semiconductor device 1.

The vertical axis of the graph on the right side of the drawing indicates the time required from when an ultrasonic wave is emitted to the upper surface of the semiconductor device 1, that is, the support substrate SS to when a predetermined reflected wave is received by the probe 10. Thus, at the interface between the liquid film Lw of the pure water and the support substrate SS, the interface between the insulating layer 50 of the layer L2 and the cavity defect V12 on the bonding surface B12, and the interface between the semiconductor substrate SB and the atmosphere outside the semiconductor substrate SB, as the depth from the upper surface in the semiconductor device 1 increases, a reception time of the reflected wave generated at these interfaces is delayed.

In addition, the horizontal axis of the graph represents a signal intensity of the received reflected wave. The signal intensity of the reflected wave is represented by, for example, an amplitude centered on ±0. The graph in FIG. 5 illustrates a state in which a reflected wave having a predetermined signal intensity is detected at each interface.

An inspection method for performing detection of the cavity defects V12, V23, and the like by transmitting and receiving the ultrasonic wave through the pure water or the like as described above is also referred to as a water immersion method or the like.

Note that FIG. 5 illustrates an example in which, in detection of a cavity defect in the layers L1 to L3 sandwiched between the semiconductor substrate SB and the support substrate SS, inspection is performed by emitting the ultrasonic wave from the support substrate SS side with the support substrate SS as the upper surface. However, which side of the semiconductor substrate SB side or the support substrate SS side the ultrasonic wave is emitted from is arbitrary.

In addition, as described above, the cavity defect inspection of the semiconductor device 1 in the middle of manufacturing is performed also at the stage when the first bonding is completed. That is, in this case, the ultrasonic wave is emitted from the support substrate SS side or the semiconductor substrate SB side to the layers L1 and L2 sandwiched between the semiconductor substrate SB and the support substrate SS, to perform inspection of a cavity defect.

### Inspection Method for Semiconductor Device

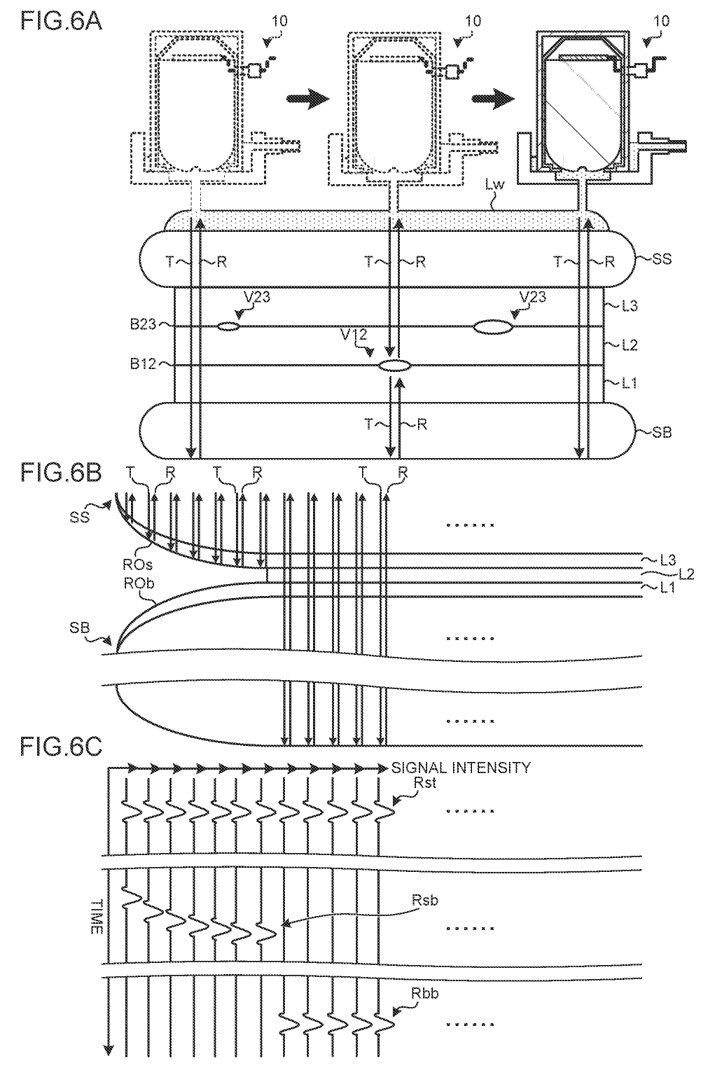

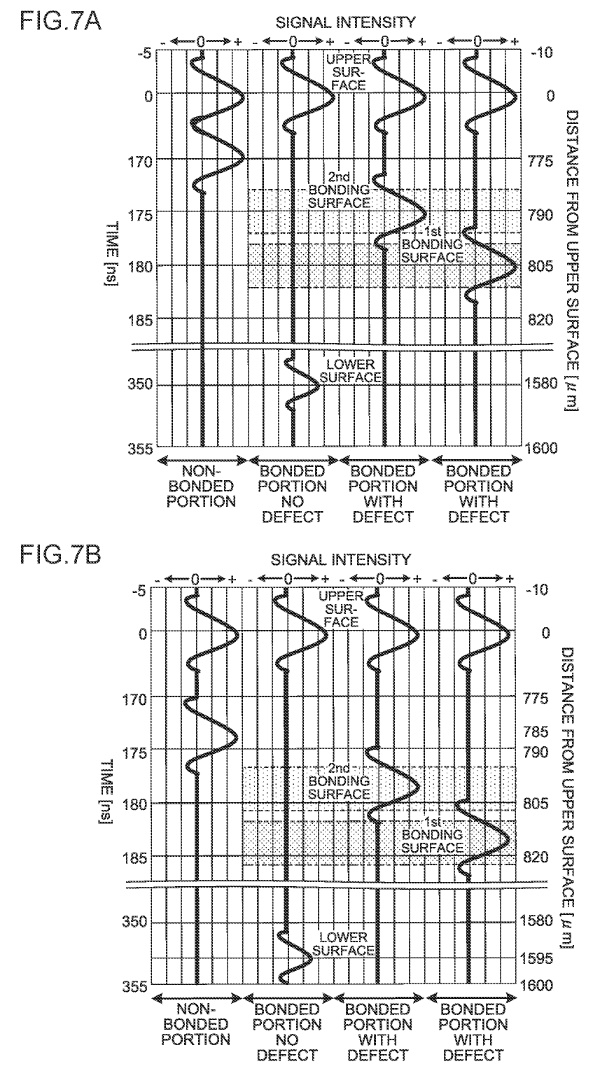

Next, with reference to FIGS. 6A to 7B, a detailed description will be given of an inspection method for the semiconductor device 1 by the inspection apparatus 2 described above.

FIGS. 6A to 6C are schematic diagrams illustrating the inspection method for the semiconductor device 1 by the inspection apparatus 2 according to the embodiment.

As illustrated in FIG. 6A, in the inspection of the cavity defect generated in the semiconductor device 1, while the probe 10 of the inspection apparatus 2 is moved, for example, along the upper surface of the support substrate SS or the like, the ultrasonic wave T is transmitted at a plurality of points, and the reflected wave R obtained is analyzed for each point. The number and arrangement of measurement points are arbitrary, and for example, individual points may be arranged in a grid shape, may be arranged concentrically, or may be arranged in a spiral shape when viewed from the upper surface of the semiconductor device 1. In addition, the number of measurement points per unit area of the support substrate SS, that is, the measurement density may be uniform or may vary in a surface of the support substrate SS.

As a result, it is possible to specify the presence or absence, the numbers, the sizes, and the positions of the cavity defects V12 and V23 in the surfaces of the individual bonding surfaces B12 and B23. Here, the sizes of the cavity defects V12 and V23 may be the areas of the cavity defects V12 and V23 when viewed from the upper surface of the support substrate SS.

In addition, at this time, the reflected wave R that is relatively large is obtained from the upper surface of the support substrate SS, and thicknesses of the individual layers L1 to L3 are known from a design value or the like of the semiconductor device 1, and thus, in principle, depths of the bonding surfaces B12 and B23 from the upper surface of the support substrate SS can also be specified. Thus, it seems easy to estimate how long it takes to receive the reflected waves R from the cavity defect V12 generated in the bonding surface B12 and the cavity defect V23 generated in the bonding surface B23 after obtaining the reflected wave R indicating the upper surface of the support substrate SS.

However, there is an individual difference in thicknesses of the support substrate SS, the semiconductor substrate SB, and the like, and an error of, for example, about ±20 μm may occur between the different support substrates SS or between the different semiconductor substrates SB. Thus, in the inspection method of the embodiment, thickness measurement is also performed of the support substrate SS or the semiconductor substrate SB on a side from which the ultrasonic wave is emitted at the time of inspecting the semiconductor device 1. FIG. 6B below illustrates a state in which the thickness of the support substrate SS is measured.

Note that, as described in detail below, in actual processing by the processor 21 in the inspection apparatus 2, it is not always necessary to calculate the thickness itself of the support substrate SS, and a purpose of the processing is to adjust detection timings of waveforms from the respective cavity defects V12 and V23. In the present specification, for convenience of description, expressions may be used such as “measurement of”, “measure”, and “estimate” the thickness of the support substrate SS, but this does not mean that the processor 21 actually calculates, estimates, or acquires the thickness of the support substrate SS.

As illustrated in FIG. 6B, in order to measure the thickness of the support substrate SS, more precisely, in order to reflect the thickness of the support substrate SS in the detection timings of the cavity defects V12 and V23, the reflected wave R is acquired by emission of the ultrasonic wave T to a non-bonded portion of the support substrate SS, that is, an outer edge portion of the support substrate SS not overlapping the bonded portion of the layers L1 to L3 in the vertical direction.

The support substrate SS, which is a semiconductor substrate or the like, includes a roll-off portion ROs having a predetermined width at the outer edge portion. In the roll-off portion ROs, the thickness of the support substrate SS is gradually thinner at a position closer to an outermost edge portion. In the thickness measurement of the support substrate SS, emission of the ultrasonic wave T and reception of the reflected wave R are performed at a plurality of points from the outermost edge portion of the support substrate SS including the roll-off portion ROs having such a shape to a predetermined distance inside the support substrate SS.

Note that, the layer L3 disposed on the support substrate SS may be formed to extend to the outer edge portion of the support substrate SS including the roll-off portion ROs as illustrated in FIG. 6B. Thus, the reflected wave R of the ultrasonic wave T in the roll-off portion ROs may be substantially reflected on the outermost surface (lowermost surface in the drawing) of the layer L3, the outermost surface being out of the bonding surface B23 with the layer L2. Even in this case, since the thickness of the layer L3 is known and the error between the different support substrates SS is small, the thickness of the support substrate SS can be estimated in consideration of the thickness of the layer L3.

The waveform of the ultrasonic wave T including the reflected wave R thus obtained is illustrated in graphs in FIG. 6C. The vertical axis of the graphs represents the time required from when the ultrasonic wave T is emitted to the support substrate SS to when a predetermined reflected wave is received. The horizontal axes of the graphs corresponding to individual waveforms are the signal intensities of the received reflected waves, respectively.

As illustrated in FIG. 6C, in measurement performed a predetermined number of times from the outermost edge portion toward the inside of the support substrate SS, a reflected wave Rst on the upper surface of the support substrate SS is initially obtained, and then a reflected wave Rsb on the non-bonded lower surface of the support substrate SS, that is, the lower surface of the exposed layer L3 is obtained. At this time, the time required for detection of the reflected wave Rsb from the lower surface of the support substrate SS gradually increases according to the shape of the roll-off portion ROs.

Thereafter, when the measurement continues to be performed at a further inner position from the outermost edge portion of the support substrate SS and the position reaches a position overlapping with the bonded portions of the individual layers L1 to L3 in the vertical direction, if none of the cavity defects V12 and V23 is included in these portions, the reflected wave Rst on the upper surface of the support substrate SS is obtained, and then a reflected wave Rbb from the lower surface of the semiconductor substrate SB is detected with the ultrasonic wave transmitted through the support substrate SS and the layers L3 to L1.

At this time, it can be considered that the thickness of the support substrate SS based on a time when the reflected wave Rsb from the lower surface of the non-bonded portion of the support substrate SS is received, the thickness being obtained immediately before the reflected wave Rbb from the lower surface of the semiconductor substrate SB is first detected, is substantially equal to a net thickness of the support substrate SS excluding the roll-off portion ROs.

On the basis of measurement results obtained as described above, the processor 21 of the inspection apparatus 2 estimates a time when the cavity defect V12 generated in the bonding surface B12 is detected and a time when the cavity defect V23 generated in the bonding surface B23 is detected.

As described above, the content described above as the thickness measurement of the support substrate SS corresponds to determining detection periods of the individual cavity defects V12 and V23 on the basis of a time when the reflected wave Rsb immediately before transition from the non-bonded portion to the bonded portion of the support substrate SS is received as processing by the processor 21 of the inspection apparatus 2. In other words, the processor 21 of the inspection apparatus 2 sets the detection periods of the individual cavity defects V12 and V23 by setting, as a reference point, a predetermined point on the support substrate SS or the layer L3 from which the reflected wave Rsb immediately before transition from the non-bonded portion to the bonded portion of the support substrate SS is obtained.

Here, in a case where the layer L3 disposed on the support substrate SS is formed to extend to the outer edge portion of the support substrate SS, and the predetermined point on the layer L3 is set as the reference point, the detection period of the cavity defect V23 can be a period including the time when the reflected wave Rsb immediately before transition from the non-bonded portion to the bonded portion of the support substrate SS is received, or the like. Thus, substantially only calculation of the detection period of the cavity defect V12 may be performed as the processing by the processor 21.

Note that, similarly to the support substrate SS above the layer L3, the semiconductor substrate SB below the layer L1 includes a roll-off portion ROb in which the thickness of the semiconductor substrate SB is gradually thinner at a position closer to the outermost edge portion. Thus, also when performing detection of the cavity defects V12 and V23 by emitting the ultrasonic wave not from the support substrate SS side but from the semiconductor substrate SB side, it is possible to perform thickness measurement of the semiconductor substrate SB similarly to the case of the support substrate SS, and set the detection period for each of the cavity defects V12 and V23 on the basis of the thickness measurement.

The above processing is preferably performed a plurality of times at different positions with respect to an edge portion of the support substrate SS. More preferably, the entire outer periphery of the support substrate SS is measured at a plurality of points at predetermined intervals, and the detection periods can be set for the individual cavity defects V12 and V23 on the basis of an average value of results obtained from these points.

In measurement of these points, for one measurement point, it is not always necessary to perform the measurement from the outermost edge portion toward the inside of the support substrate SS as described above, and the measurement may be performed from the inside toward the outermost edge portion of the support substrate SS. In this case, it can be considered that the thickness of the support substrate SS based on a time when the reflected wave Rsb from the lower surface of the non-bonded portion of the support substrate SS is received, the thickness being obtained immediately after the reflected wave Rbb from the lower surface of the semiconductor substrate SB is last detected, is substantially equal to the net thickness of the support substrate SS excluding the roll-off portion ROs.

As described above, even in a case where the measurement is performed in any order, it can be considered that the reflected wave Rsb having a longest reception time among the reflected waves Rsb from the lower surface of the non-bonded portion of the support substrate SS represents the net thickness of the support substrate SS excluding the roll-off portion ROs.

FIGS. 7A and 7B are schematic graphs illustrating an example of an inspection result for the semiconductor device 1 obtained by the inspection apparatus 2 according to the embodiment. The vertical axis of the graph represents a time (ns) from when the ultrasonic wave is emitted to the support substrate SS to when a predetermined reflected wave is received. The horizontal axis of the graph represents a signal intensity of the obtained reflected wave.

In addition, it is assumed that the thickness of the support substrate SS is different between FIGS. 7A and 7B. Note that, each of the graphs in FIGS. 7A and 7B illustrates, in order from the left side of the drawing, a reflected wave of the non-bonded portion indicating the thickness of the support substrate SS, and in the bonded portion of the support substrate SS, a reflected wave in a case where the cavity defects V12 and V23 are not present in any of the bonding surface B12 that is the first bonding surface (in the drawing, 1st bonding surface) and the bonding surface B23 that is the second bonding surface (in the drawing, 2nd bonding surface), a reflected wave in a case where the cavity defect V23 is present in the bonding surface B23 that is the second bonding surface, and a reflected wave in a case where the cavity defect V12 is present in the bonding surface B12 that is the first bonding surface.

As illustrated in FIG. 7A, when a timing at which a reflected wave from the upper surface of the support substrate SS is detected is 0 ns, the next reflected wave is obtained at 170 ns thereafter in the non-bonded portion, and the reflected wave is considered to be a reflected wave from the lower surface of the support substrate SS. In this case, the thickness of the support substrate SS is estimated to be 775 μm.

On the basis of the fact that the reflected wave from the lower surface of the support substrate SS is received at 170 ns, the processor 21 sets, as detection periods of the respective cavity defects V12 and V23, periods in which the cavity defect V12 on the bonding surface B12 and the cavity defect V23 on the bonding surface B23 are respectively expected to be detected in the semiconductor device 1 as the inspection target at this time.

In the example of FIG. 7A, the processor 21 sets a period during which a reflected wave from the cavity defect V23 is detected on the bonding surface B23 at a shallow position from the upper surface of the support substrate SS to, for example, a period of greater than or equal to 173 ns and less than or equal to 177 ns indicated by a one-dot chain line in the drawing. In addition, the processor 21 sets a period during which a reflected wave from the cavity defect V12 is detected on the bonding surface B12 at a deep position from the upper surface of the support substrate SS to, for example, a period of greater than or equal to 178 ns and less than or equal to 182 ns indicated by a two-dot chain line in the drawing.

Note that a length of the detection period of the reflected wave from each of the cavity defects V23 and V12 is determined, for example, by addition of the thickness of the support substrate SS and the thickness of each of the layers L3 and L2 confirmed by aggregation results of cross-section analysis, film forming conditions, and the like performed in advance. Note that, it is considered that an in-plane thickness error of the support substrate SS and variation in the thickness of the layers L3 and L2 are in a range of about ±0.2 μm and sufficiently small in comparison with the fact that the thicknesses between the different support substrates SS can vary in a range of about ±20 μm.

In the second waveform of the bonded portion from the left side of the drawing of the graph in FIG. 7A, the reflected wave is not detected in any of the period of greater than or equal to 173 ns and less than or equal to 177 ns, which is the detection period of the reflected wave from the cavity defect V23, and the period of greater than or equal to 178 ns and less than or equal to 182 ns, which is the detection period of the reflected wave from the cavity defect V12. Thus, the processor 21 determines that none of the cavity defects V12 and V23 is generated in this portion. A reflected wave detected at 350 ns thereafter is considered to be a reflected wave from the back surface of the semiconductor substrate SB located below the layers L1 to L3.

In the third waveform of the bonded portion from the left side of the drawing of the graph in FIG. 7A, a reflected wave is detected in the period of greater than or equal to 173 ns and less than or equal to 177 ns, which is the detection period of the reflected wave from the cavity defect V23. Thus, the processor 21 determines that the cavity defect V23 is generated in the bonding surface B23, in this portion. Note that the processor 21 specifies the size of the cavity defect V23 by also performing comparison with waveforms at measurement points before and after the measurement point, for example.

In the waveform of the bonded portion at the right end of the drawing of the graph in FIG. 7A, a waveform is detected in the period of greater than or equal to 178 ns and less than or equal to 182 ns, which is the detection period of the reflected wave from the cavity defect V12. Thus, the processor 21 determines that the cavity defect V12 is generated in the bonding surface B12, in this portion. Note that, the cavity defect V12 on the bonding surface B12 is a cavity defect that has been inspected at a time point at which bonding of the layers L1 and L2 is completed, and can be excluded from the current inspection target and determination target. This is because it is considered that the cavity defect V12 remaining on the bonding surface B12 is determined in the previous inspection that re-bonding is unnecessary because the cavity defect V12 is generated but has a size less than the predetermined size, and the process proceeds to the next process.

As illustrated in FIG. 7B, when a timing at which a reflected wave from the upper surface of the support substrate SS is detected is 0 ns, the next reflected wave is obtained at 173 ns thereafter in the non-bonded portion, and the reflected wave is considered to be a reflected wave from the lower surface of the support substrate SS. In this case, the thickness of the support substrate SS is estimated to be 785 μm.

On the basis of the fact that the reflected wave from the lower surface of the support substrate SS is received at 173 ns, the processor 21 sets, as detection periods of reflected waves from the respective cavity defects V12 and V23, periods in which the cavity defect V12 on the bonding surface B12 and the cavity defect V23 on the bonding surface B23 are respectively expected to be detected in the semiconductor device 1 as the inspection target at this time.

In the example of FIG. 7B, the processor 21 sets a period during which a reflected wave from the cavity defect V23 is detected on the bonding surface B23 at a shallow position from the upper surface of the support substrate SS to, for example, a period of greater than or equal to 176.5 ns and less than or equal to 180.5 ns. In addition, the processor 21 sets a period during which a reflected wave from the cavity defect V12 is detected on the bonding surface B12 at a deep position from the upper surface of the support substrate SS to, for example, a period of greater than or equal to 182 ns and less than or equal to 186 ns.

In the second waveform of the bonded portion from the left side of the drawing of the graph in FIG. 7B, the reflected wave is not detected in any of the period of greater than or equal to 176.5 ns and less than or equal to 180.5 ns, which is the detection period of the reflected wave from the cavity defect V23, and the period of greater than or equal to 182 ns and less than or equal to 186 ns, which is the detection period of the reflected wave from the cavity defect V12. Thus, the processor 21 determines that none of the cavity defects V12 and V23 is generated in this portion. A reflected wave detected at 353 ns thereafter is considered to be a reflected wave from the back surface of the semiconductor substrate SB located below the layers L1 to L3.

In the third waveform of the bonded portion from the left side of the drawing of the graph in FIG. 7B, a reflected wave is detected in a period of greater than or equal to 176.5 ns and less than or equal to 180.5 ns, which is a detection period of the reflected wave from the cavity defect V23. Thus, the processor 21 determines that the cavity defect V23 is generated in the bonding surface B23, in this portion. Note that the processor 21 specifies the size of the cavity defect V23 by also performing comparison with waveforms at measurement points before and after the measurement point, for example.

In the waveform of the bonded portion at the right end of the drawing of the graph in FIG. 7B, a waveform is detected in the period of greater than or equal to 182 ns and less than or equal to 186 ns, which is a detection period of the reflected wave from the cavity defect V12. Thus, the processor 21 determines that the cavity defect V12 is generated in the bonding surface B12, in this portion. Note that the cavity defect V12 on the bonding surface B12 can be excluded from the current inspection target and determination target.

As described above, in the inspection method of the embodiment, in inspection of a predetermined semiconductor device 1, measurement is performed of the thickness of the support substrate SS on a side from which the ultrasonic wave is emitted, and a detection period is appropriately set for each of the cavity defects V12 and V23 on the basis of a measurement result of the measurement. As a result, even in a case where there is variation in the thickness of the support substrate SS, it is possible to specify with high accuracy which one of the cavity defects V12 and V23 the received reflected wave is derived from.

### Comparative Example

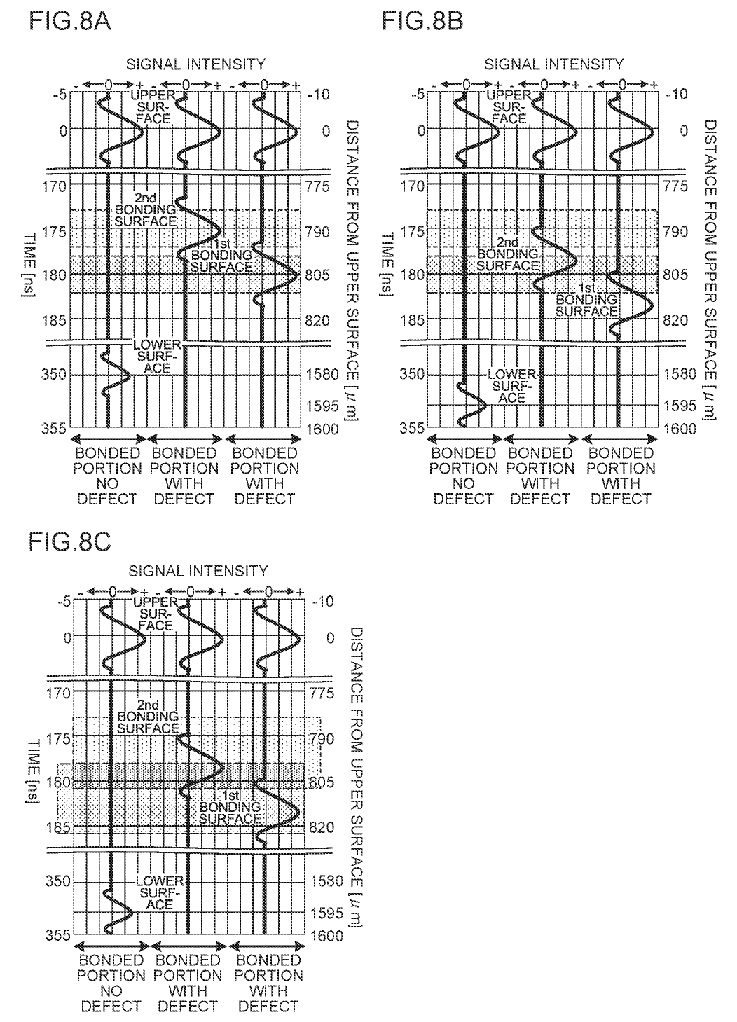

Some semiconductor devices, such as a semiconductor device including a memory region and a peripheral circuit, may be manufactured by forming of individual constituent elements on different substrates and bonding of the substrates. At this time, it is inspected whether or not a cavity defect is generated on a bonding surface, and re-bonding or the like is performed as necessary. However, in a semiconductor device having a plurality of bonding surfaces by a plurality of times of bonding, it may be difficult to distinguish whether the detected cavity defect is caused by the most recent bonding or the previous bonding due to variation in the thickness of the substrate on a side from which the ultrasonic wave is emitted, or the like. Such examples are illustrated in FIGS. 8A to 8C.

FIGS. 8A to 8C are schematic graphs illustrating an example of an inspection result for the semiconductor device obtained by an inspection apparatus according to a comparative example.

FIG. 8A is an example of a case where the thickness of the support substrate is 775 μm, and FIG. 8B is an example of a case where the thickness of the support substrate is 785 μm. However, in an inspection method of the comparative example, the thickness measurement of the support substrate is not performed, and detection periods of reflected waves from respective cavity defects in the plurality of bonding surfaces are uniformly determined for respective bonding surfaces. In the examples of FIGS. 8A and 8B, the detection period of the reflected wave from the cavity defect generated on the bonding surface at a shallow position from the support substrate is determined to be greater than or equal to 173 ns and less than or equal to 177ns. In addition, the detection period of the reflected wave from the cavity defect generated on the bonding surface at a deep position from the support substrate is determined to be greater than or equal to 178 ns and less than or equal to 182ns.

As illustrated in FIG. 8A, in the waveform at the left end of the drawing, a detection timing of the reflected wave from the upper surface of the support substrate is set as 0ns, and the reflected wave considered to be the reflected wave from the back surface of the semiconductor substrate located below the plurality of layers is detected at 350 ns. A processor of an inspection apparatus of the comparative example determines that no cavity defect is generated in this portion.

In addition, in the second and third waveforms of the bonded portion from the left side of the drawing of the graph in FIG. 8A, the reflected waves are generated in the period of greater than or equal to 173 ns and less than or equal to 177 ns and the period of greater than or equal to 178 ns and less than or equal to 182 ns, respectively, and the processor of the comparative example determines that the reflected waves are the cavity defect generated on the bonding surface at the shallow position from the support substrate and the cavity defect generated on the bonding surface at the deep position from the support substrate, respectively.

As illustrated in FIG. 8B, in the waveform at the left end of the drawing, a detection timing of the reflected wave from the upper surface of the support substrate is set as 0 ns, and the reflected wave considered to be the reflected wave from the back surface of the semiconductor substrate located below the plurality of layers is detected at 353 ns. A processor of an inspection apparatus of the comparative example determines that no cavity defect is generated in this portion.

In addition, in the second and third waveforms of the bonded portion from the left side of the drawing of the graph in FIG. 8B, the reflected waves are generated in the period of greater than or equal to 178 ns and less than or equal to 182 ns and a later period being out of any detection period, respectively, and the processor of the comparative example cannot correctly determine that the reflected waves represent the cavity defect generated on the bonding surface at the shallow position from the support substrate and the cavity defect generated on the bonding surface at the deep position from the support substrate, respectively.

Thus, in the example of FIG. 8C, the detection periods of the respective cavity defects are set again so that both the detection timing of each cavity defect in FIG. 8A and the detection timing of each cavity defect in FIG. 8B are included. That is, the detection period of the cavity defect generated on the bonding surface at the shallow position from the support substrate is set as a period of greater than or equal to 173 ns and less than or equal to 180.5 ns, and the detection period of the cavity defect generated on the bonding surface at the deep position from the support substrate is set as a period of greater than or equal to 178 ns and less than or equal to 186 ns.

However, in this case, since the detection periods of the individual cavity defects partially overlap with each other, even in this case, the processor of the comparative example cannot correctly determine that the reflected waves represent the cavity defect generated on the bonding surface at the shallow position from the support substrate and the cavity defect generated on the bonding surface at the deep position from the support substrate, respectively.

According to the inspection apparatus 2 of the embodiment, the processor 21 estimates a time required for reception of a reflected wave reflected by the cavity defect V23 on the basis of a time from when the ultrasonic wave is emitted from the upper surface side of the support substrate SS to the edge portion of the support substrate SS by the probe 10, the edge portion being out of the bonding surfaces B12 and B23, to when a reflected wave reflected by the edge portion of the support substrate SS is received by the probe 10, and sets a detection period of the cavity defect V23 on the basis of the time estimated. In addition, a time required for reception of a reflected wave reflected by the cavity defect V12 is estimated on the basis of the time until the reflected wave reflected by the edge portion of the support substrate SS is received, and a detection period of the cavity defect V12 is set on the basis of the time estimated.

As a result, the detection periods of the individual cavity defects V12 and V23 can be set according to the thickness of the support substrate SS, so that inspection accuracy for the cavity defects V12 and V23 using the ultrasonic wave can be improved. In addition, since detection times of the individual cavity defects V12 and V23 can be estimated with higher accuracy, the individual detection periods can be set to be short, and it is possible to specify with high accuracy which one of the cavity defects V12 and V23 the received reflected wave is caused by.

In addition, with the above configuration, adjustment of the detection period according to the thickness of the support substrate SS can be performed in parallel at the time of the cavity defect inspection. In this case, since work of individually measuring the thickness of the support substrate SS is unnecessary, efficiency of the work can be improved, conditions of the thickness measurement of the support substrate SS and the cavity defect inspection can be matched, and the inspection accuracy can be further improved.

According to the inspection apparatus 2 of the embodiment, the processor 21 causes the probe 10 to perform transmission of the ultrasonic wave and reception of a reflected wave with respect to a plurality of points of the roll-off portion ROs of the support substrate SS, and sets detection periods of the individual cavity defects V12 and V23 on the basis of a point of the plurality of points, the point being a point for which a time from when the ultrasonic wave is emitted to when the reflected wave is received is the longest. As a result, the thickness of the support substrate SS can be measured with higher accuracy.

Note that, in the above-described embodiment, when the thickness of the support substrate SS or the like is measured, measurement is performed for a plurality of points of the edge portion of the non-bonded portion of the support substrate SS, and the thickness of the support substrate SS is specified on the basis of a point for which the time from when the ultrasonic wave is emitted to when the reflected wave is received is the longest. However, a method of specifying the thickness of the support substrate SS is not limited to the above.

As an example, it is also possible to specify the thickness of the support substrate SS by performing measurement for a plurality of points of the edge portion of the non-bonded portion of the support substrate SS and using exponential approximation of the time from when the ultrasonic wave is emitted to when the reflected wave is received in pieces of measurement data of the plurality of points.

### First Modification

In the above-described embodiment, an example has been described in which the thickness of the support substrate SS including the roll-off portion ROs is measured to improve the inspection accuracy for the cavity defects V12 and V23. However, the roll-off portion ROs of the support substrate SS may be removed during processing of bonding the individual layers L1 to L3.

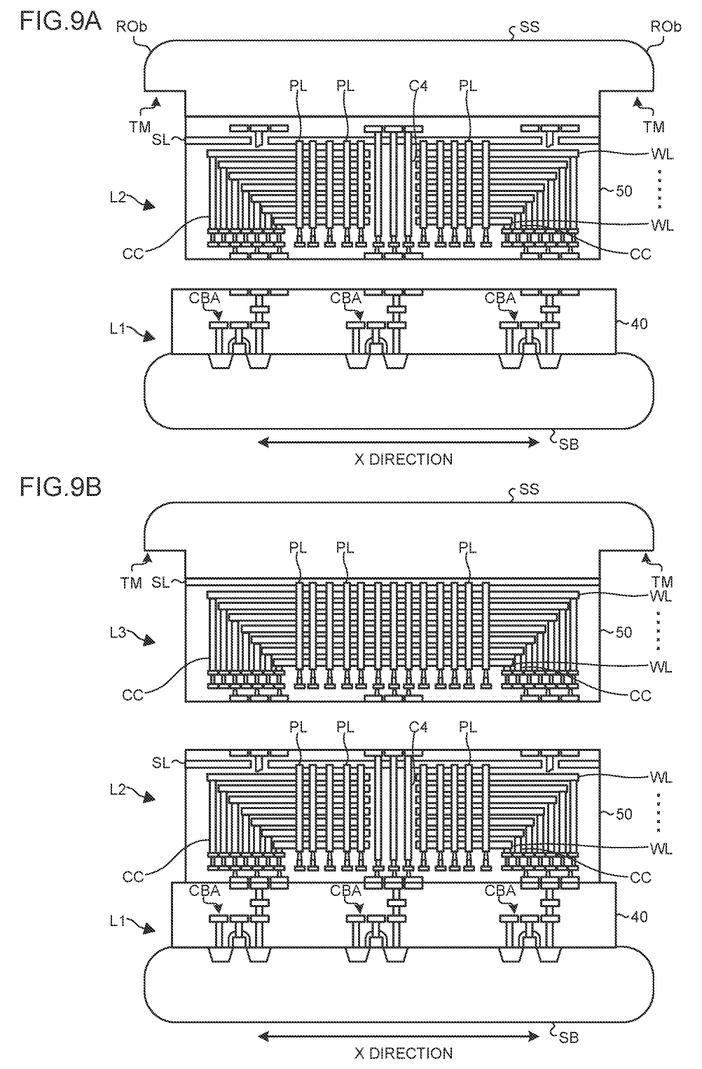

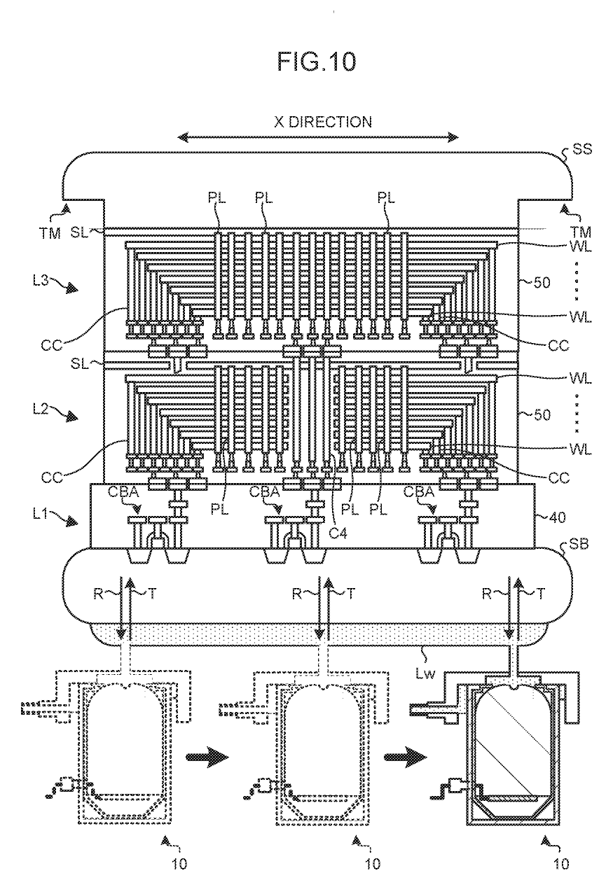

Hereinafter, in a first modification, with reference to FIGS. 9A to 10, a description will be given of an example of a case where the support substrate SS does not include the roll-off portion ROs.

FIGS. 9A to 10 are diagrams sequentially exemplifying a part of a procedure of a method for manufacturing the semiconductor device according to the first modification of the embodiment. In FIGS. 9A to 10, components similar to those of the above-described embodiment are denoted by similar reference numerals, and the description thereof may be omitted.

As illustrated in FIG. 9A, after each of configurations of the layer L2 is formed on the support substrate SS, the outer edge portions of the layer L2 and the support substrate SS are trimmed and removed by use of, for example, a dicing saw or the like. The layer L2 is trimmed over the entire thickness direction of the layer L2. The support substrate SS is trimmed from a surface on a side on which the layer L2 is formed to a predetermined depth, so that the support substrate SS includes a trimming portion TM having a flat surface instead of the roll-off portion ROs that is gently inclined, at the outer edge portion on the side on which the layer L2 is formed. The roll-off portion ROs on the upper surface side of the support substrate SS remains as it is.

Thereafter, the support substrate SS and the semiconductor substrate SB on which each of configurations of the layer L1 is formed are bonded together, and the support substrate SS is ground and removed. By the above-described trimming, a surface of the layer L2 to be bonded to the layer L1 may have an area smaller than an area of a surface of the layer L1. In addition, since the areas of the support substrate SS and the layer L2 overlap each other substantially equally at the interface between the support substrate SS and the layer L2 by the above-described trimming, chipping of the outer edge portion of the layer L2 is suppressed at the time of grinding and removing the support substrate SS.

As illustrated in FIG. 9B, also in the new support substrate SS, after each of configurations of the layer L3 is formed, the outer edge portions of the layer L3 and the support substrate SS are trimmed and removed by use of, for example, a dicing saw or the like. As a result, the new support substrate SS also includes the trimming portion TM having a flat surface instead of the roll-off portion ROs at the outer edge portion on a side on which the layer L3 is formed. The roll-off portion ROs on the upper surface side of the support substrate SS remains as it is.

Thereafter, the support substrate SS on which the layer L3 has been formed and trimmed is bonded to the semiconductor substrate SB including the layers L1 and L2. By the above-described trimming, a surface of the layer L3 bonded to the layer L2 has an area substantially equal to an area of a surface of the layer L2. In addition, by the above-described trimming, chipping of the layer L3 at the time of grinding and removing the support substrate SS is also suppressed.

The semiconductor device obtained as described above after the layers L1 to L3 are bonded together may not include the roll-off portion ROs in the non-bonded portion of the support substrate SS, and may be in a state unsuitable for the thickness measurement of the support substrate SS by the method of the above-described embodiment.

As illustrated in FIG. 10, in the cavity defect inspection of the semiconductor device in which the support substrate SS does not include the roll-off portion ROs, it is possible to emit the ultrasonic wave T from the semiconductor substrate SB side, measure the thickness of the semiconductor substrate SB by the reflected wave R obtained, set the detection periods of the individual cavity defects V12 and V23, and search for the individual cavity defects V12 and V23.

Note that, also when inspection of the cavity defect V12 on the bonding surface B12 is performed after the first bonding, the inspection can be performed by emission of the ultrasonic wave not from the trimmed support substrate SS side but from the semiconductor substrate SB side.

### Second Modification

In the above-described embodiment, an example has been described in which the detection periods of the cavity defects V12 and V23 are set according to the thickness of the support substrate SS. However, the detection periods of the cavity defects V12 and V23 may be set by use of a reference other than the thickness of the support substrate SS.

As an example, in a case where there is a cavity whose depth position from the front surface of a semiconductor device as an inspection target is known in any of the layers L1 to L3, the cavity can be used as a reference. The cavity whose depth position is known may be formed artificially, for example, or may be formed by predetermined processing in a process of manufacturing the semiconductor device.

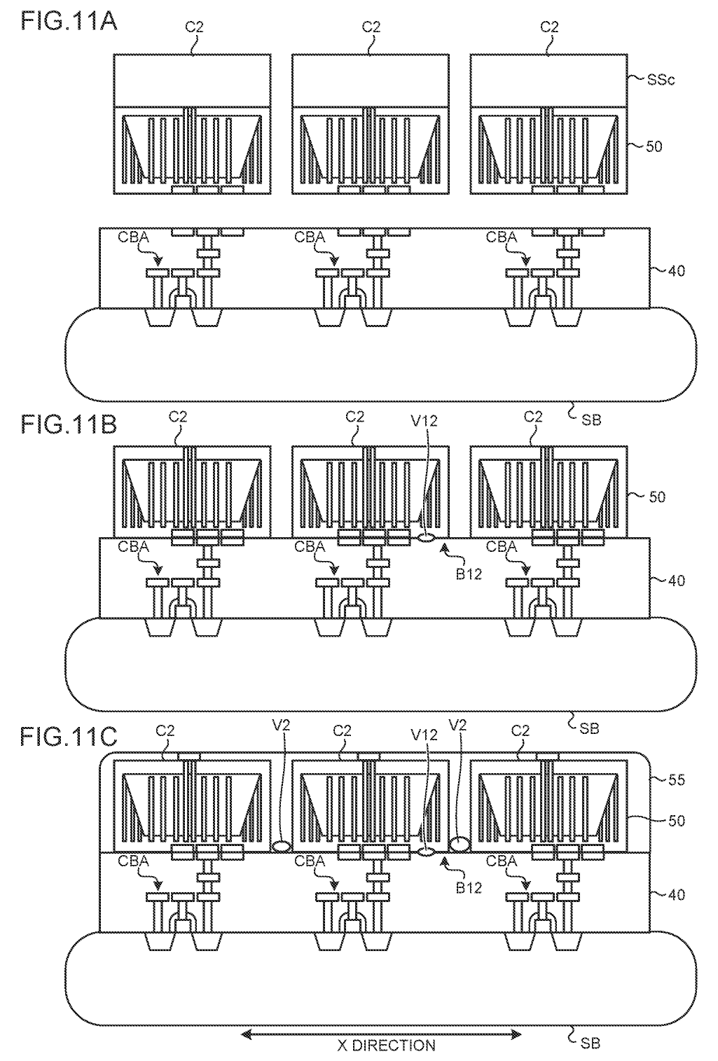

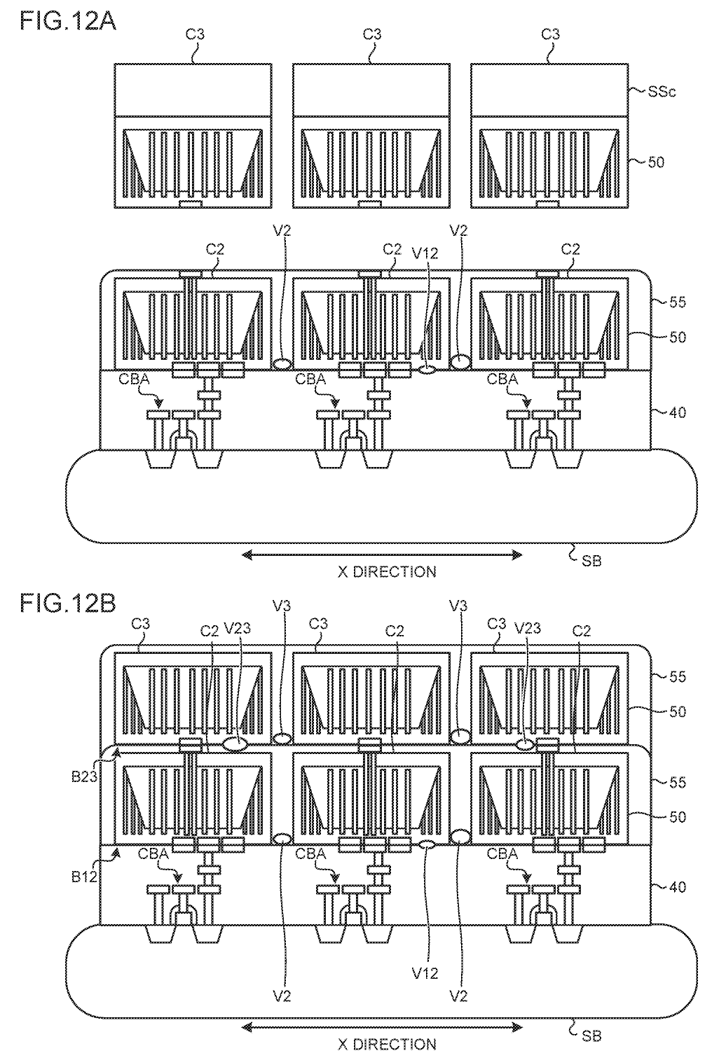

Hereinafter, in a second modification, with reference to FIGS. 11A to 12B, a description will be given of an example of a case where cavities V2 and V3 whose depth positions are known are formed by the predetermined processing in the process of manufacturing the semiconductor device.

FIGS. 11A to 12B are cross-sectional views sequentially exemplifying a part of a method for manufacturing the semiconductor device according to the second modification of the embodiment. Note that, in FIGS. 11A to 12B, components similar to those of the above-described embodiment are denoted by similar reference numerals, and the description thereof may be omitted.

As illustrated in FIGS. 11A to 12B, in the second modification, the semiconductor device is bonded to the semiconductor substrate SB including the peripheral circuits CBA after a plurality of the memory regions MR and the like included in the layers L2 and L3 are individually singulated. Such a bonding method is also referred to as Die-to-Wafer Bonding or the like. Note that a method of bonding wafers together as in the above-described embodiment and first modification is also referred to as Wafer-to-Wafer Bonding or the like.

As illustrated in FIG. 11A, in a Die-to-Wafer Bonding method, for example, after each of configurations of the layer L2 is formed on the support substrate SS, the plurality of configurations in the layer L2 including the memory region MR and the like is singulated into individual chips C2. The individual chips C2 each include the memory region MR and the like covered with the insulating layer 50 and a support substrate SSc singulated.

As illustrated in FIG. 11B, these chips C2 are bonded to the semiconductor substrate SB so as to respectively correspond to the individual peripheral circuits CBA in the layer L1. At this time, the cavity defect V12 may be generated on the bonding surface B12 between the insulating layer 40 on the semiconductor substrate SB side and the insulating layer 50 on the chips C2 side. Thereafter, the support substrates SSc included in the individual chips C2 are ground and removed.

As illustrated in FIG. 11C, in order to fill a gap between the individual chips C2, an insulating layer 55 entirely covering the chips C2 is formed. At this time, an unfilled portion may remain in the insulating layer 55 between the individual chips C2, and the cavity V2 may be generated. From the knowledge that the cavity V2 generated in this way is easily generated, for example, at a relatively deep position near the bonding surface B12 between the insulating layers 40 and 50, and the like, a depth position of the cavity V2 from the upper surface of the insulating layer 55 can be estimated, so that the depth position is known. In addition, a depth position from the cavity V2 to the cavity defect V12 on the bonding surface B12 is also known.

As illustrated in FIG. 12A, after each of configurations of the layer L3 is formed on the new support substrate SS, the plurality of configurations in the layer L3 including the memory region MR and the like is singulated into individual chips C3. The individual chips C3 also each include the memory region MR and the like covered with the insulating layer 50 and the support substrate SSc singulated.

As illustrated in FIG. 12B, these chips C3 are bonded to the semiconductor substrate SB so as to respectively correspond to the individual peripheral circuits CBA in the layer L1 and the individual chips C2. At this time, the cavity defect V23 may be generated on the bonding surface B23 between the insulating layer 55 on the semiconductor substrate SB side and the insulating layer 50 on the chips C3 side. Thereafter, the support substrates SSc included in the individual chips C3 are ground and removed.

In addition, in order to fill a gap between the individual chips C3, the insulating layer 55 entirely covering the chips C3 is formed. At this time, an unfilled portion may remain in the insulating layer 55 between the individual chips C3, and the cavity V3 may be generated. A depth position of the cavity V3 generated in this way from the upper surface of the insulating layer 55 can also be estimated from the knowledge so far, so that the depth position is known. In addition, a depth position from the cavity V3 to the cavity defect V23 on the bonding surface B23 is also known.

When inspection of the cavity defect V23 is performed on the semiconductor device obtained as described above, the ultrasonic wave is emitted from the back surface of the semiconductor substrate SB or the upper surface of the insulating layer 55 covering the chips C3, the depth positions of the individual bonding surfaces B12 and B23 are specified by the cavities V2 and V3 serving as references, and it is possible to distinguish which one of the cavity defects V12 and V23 the acquired various reflected waves are caused by.

Note that, in a case where the ultrasonic wave is emitted from the upper surface of the insulating layer 55 covering the chips C3, there is no influence of variation in the thickness of the semiconductor substrate SB, and there is not much variation in the thickness of the insulating layers 50 included in the individual chips C2 and C3 and the insulating layer 55 covering these. However, even in this case, it is possible to perform detection of the cavity defects V12 and V23 with higher accuracy by adjusting the individual detection periods using the reference points such as the cavities V2 and V3.

In addition, in FIGS. 11A to 12B described above, an example has been described in which the detection periods of the cavity defects V12 and V23 are determined by use of the cavities V2 and V3 that can be formed in the Die-to-Wafer Bonding method. However, the method using a cavity whose depth position is known in the second modification can also be applied to a manufacturing process for the semiconductor device by wafer-to-wafer bonding such as the above-described embodiment.

According to the inspection method of the second modification, effects similar to those of the above-described embodiment are obtained.

### Third Modification

In the above-described embodiment and first and second modifications, the method has been described of improving the accuracy of the cavity defect inspection by excluding the influence of variation in the thickness of the support substrate SS, the insulating layers 50 and 55, and the like. However, there are other disturbance factors in the cavity defect inspection.

As an example of the disturbance factor in the cavity defect inspection, there is a difference in the transmission speed of the ultrasonic wave in each of configurations of the layers L2 and L3. As described above, the layers L2 and L3 include the memory region MR and the staircase region SR in which the plurality of word lines WL is stacked, and the peripheral region PR located around the memory region MR and the staircase region SR and mainly including only the insulating layer 50.

Among them, in the memory region MR and the like in which the plurality of word lines WL is stacked, the transmission speed of the ultrasonic wave is slower than that in the peripheral region PR mainly including only the insulating layer 50. Such a difference in the transmission speed of the ultrasonic wave due to a difference in the layer structure can be, for example, about 20%.

Thus, reception times of reflected waves from the cavity defects V12 and V23 may differ depending on whether each of the cavity defects V12 and V23 is at a position overlapping the memory region MR and the like in the vertical direction or at a position overlapping the peripheral region PR in the vertical direction.

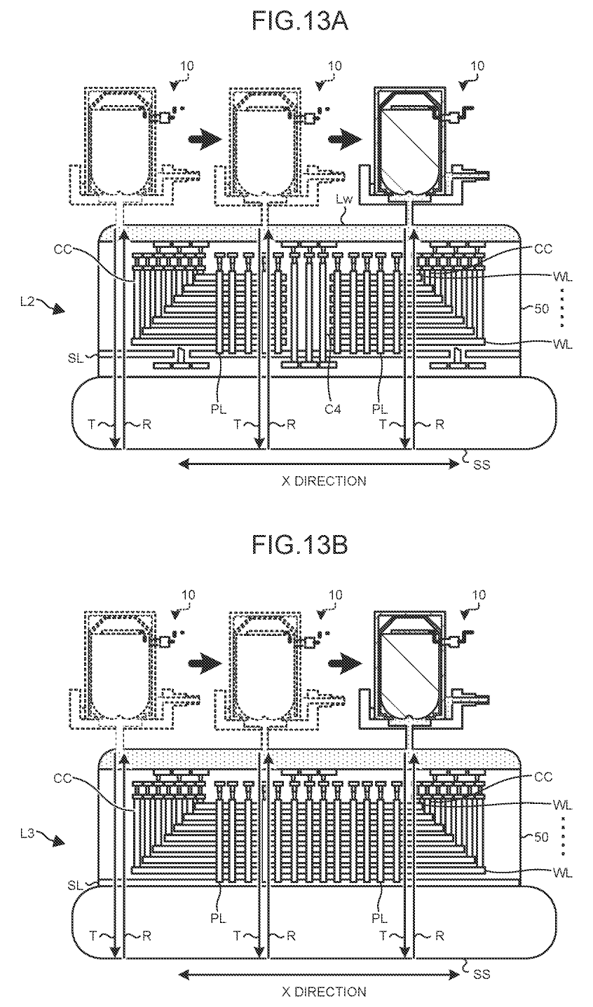

Hereinafter, in a third modification, with reference to FIGS. 13A to 15B, a description will be given of an inspection method considering the difference in the transmission speed of the ultrasonic wave in each of configurations of the layers L2 and L3. Note that, in the drawings below, components similar to those of the above-described embodiment are denoted by similar reference numerals, and the description thereof may be omitted.

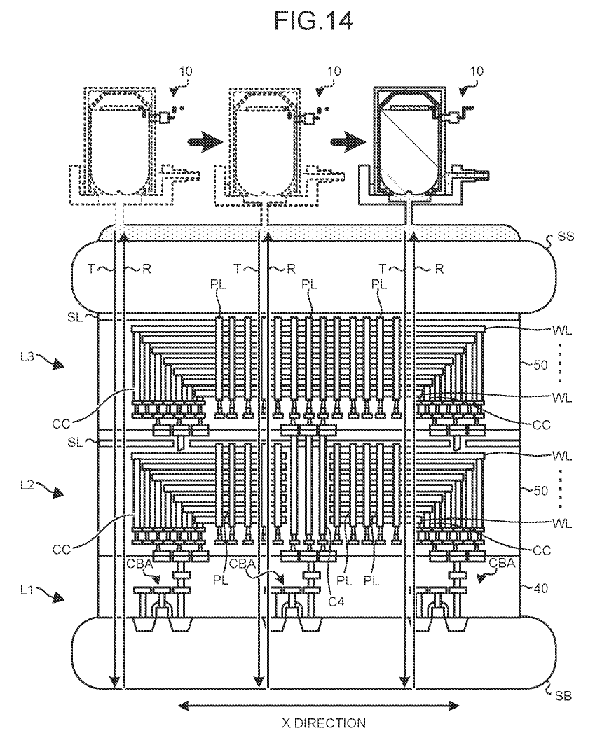

FIGS. 13A to 14 are cross-sectional views sequentially exemplifying a part of a method for manufacturing the semiconductor device according to the third modification of the embodiment.

As illustrated in FIG. 13A, in order to reflect the difference in the transmission speed of the ultrasonic wave in each of configurations of the layer L2 in the cavity defect inspection, inspection by the inspection apparatus 2 is performed in a plurality of regions along a surface of the layer L2. Such inspection is performed on the single support substrate SS on which each of configurations of the layer L2 is formed before the support substrate SS on which each of configurations of the layer L2 is formed is bonded to the semiconductor substrate SB on which each of configurations of the layer L1 is formed.

More specifically, in the plurality of regions of the layer L2, the ultrasonic wave T is emitted from the upper surface side of the layer L2, and the reflected wave R from the back surface of the support substrate SS below the layer L2 is received. As a result, the transmission speed of the ultrasonic wave T in the plurality of regions of the layer L2 can be specified on the basis of slowness and fastness of the reception time of the reflected wave R from the back surface of the support substrate SS.

At this time, the processor 21 of the inspection apparatus 2 may determine measurement points in the layer L2 while referring to design information and the like on the semiconductor device.

Thereafter, the support substrate SS on which each of configurations of the layer L2 is formed is bonded to the semiconductor substrate SB on which each of configurations of the layer L1 is formed, and the support substrate SS is ground and removed.

As illustrated in FIG. 13B, similar inspection by the inspection apparatus 2 is also performed on the support substrate SS on which each of configurations of the layer L3 is formed. That is, before the support substrate SS on which each of configurations of the layer L3 is formed is bonded to the semiconductor substrate SB including the layers L1 and L2, inspection by the inspection apparatus 2 is performed on the single support substrate SS on which each of configurations of the layer L3 is formed, in the plurality of regions along the surface of the layer L3.

More specifically, in the plurality of regions of the layer L3, the ultrasonic wave T is emitted from the upper surface side of the layer L3, and the reflected wave R from the back surface of the support substrate SS below the layer L3 is received. As a result, the transmission speed of the ultrasonic wave T in the plurality of regions of the layer L3 can be specified on the basis of slowness and fastness of the reception time of the reflected wave R from the back surface of the support substrate SS.

At this time, the processor 21 of the inspection apparatus 2 may determine measurement points in the layer L3 while referring to the design information and the like on the semiconductor device.

Thereafter, the support substrate SS on which each of configurations of the layer L3 is formed is bonded to the semiconductor substrate SB including the layers L1 and L2.

As illustrated in FIG. 14, in order to inspect the individual cavity defects V12 and V23, for example, the ultrasonic wave T is emitted from the upper surface side of the support substrate SS at a plurality of points, and the reflected wave R obtained is analyzed. At this time, the detection periods of the individual cavity defects V12 and V23 are determined on the basis of the transmission speeds of the ultrasonic wave T in the plurality of regions of the layers L2 and L3, and on the basis of the detection periods, the individual cavity defects V12 and V23 are specified.

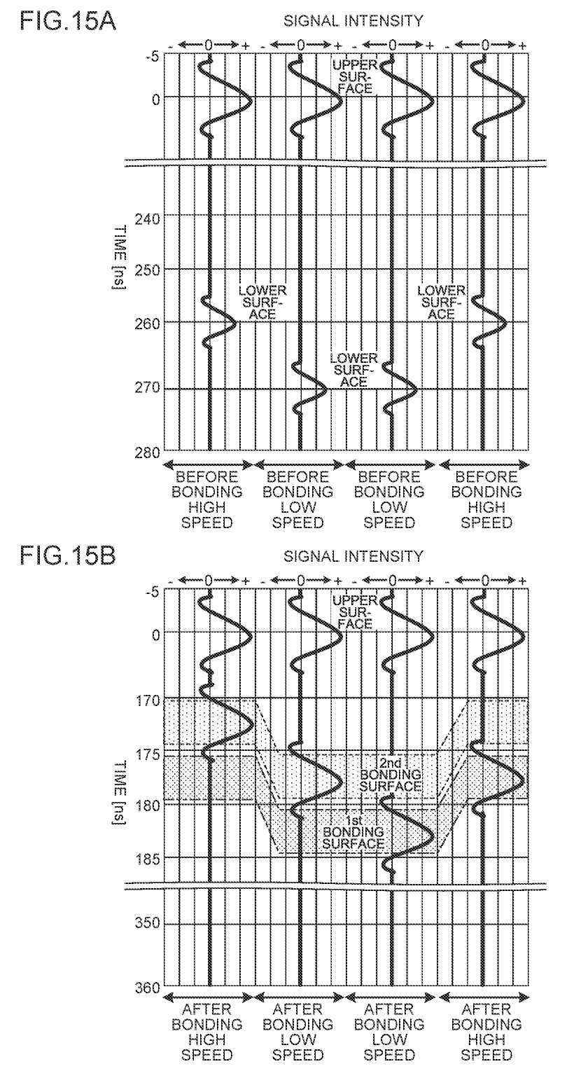

FIGS. 15A and 15B are schematic graphs illustrating an example of an inspection result for the semiconductor device obtained by an inspection method according to the third modification of the embodiment.

More specifically, FIG. 15A illustrates an inspection result of the single support substrate SS on which each of configurations of the layer L3 is formed, and the vertical axis of the graph represents a time (ns) from when the ultrasonic wave is emitted to the upper surface of the layer L3 to when a predetermined reflected wave is received. The horizontal axis of the graph represents a signal intensity of the obtained reflected wave.

In addition, FIG. 15B illustrates an inspection result for the semiconductor device after the support substrate SS on which each of configurations of the layer L3 is formed is bonded to the semiconductor substrate SB including the layers L1 and L2. The vertical axis of the graph represents a time (ns) from when the ultrasonic wave is emitted to the support substrate SS to when a predetermined reflected wave is received. The horizontal axis of the graph represents a signal intensity of the obtained reflected wave.

As illustrated in FIG. 15A, in the layer L3 before bonding, reception times of the reflected wave are different from each other for the respective individual regions, the reception times each being a time from when the reflected wave from the upper surface of the layer L3 is received to when the reflected wave transmitted through the layer L3 and reflected by the back surface of the support substrate SS is received. This means that the transmission speeds of the ultrasonic wave are different from each other for the respective plurality of regions of the layer L3. In the example of FIG. 15A, in the region where the transmission speed of the ultrasonic wave is high, the reflected wave from the back surface of the support substrate SS is received at 260 ns, and in the region where the transmission speed of the ultrasonic wave is low, the reflected wave from the back surface of the support substrate SS is received at 270 ns.

The processor 21 of the inspection apparatus 2 calculates the transmission speed of the ultrasonic wave for each individual region of the layer L3 from such a result, and stores the transmission speed in the storage device 24 (see FIG. 5) or the like, for example.

As illustrated in FIG. 15B, in the inspection of the semiconductor device in which the layers L1 to L3 have been bonded together, the processor 21 sets the detection periods of the cavity defects V12 and V23 for each individual region on the basis of the transmission speed of the ultrasonic wave in each region of the layer L3 stored in the storage device 24 or the like.

That is, the processor 21 sets the detection period of the cavity defect V23 to, for example, greater than or equal to 171 ns and less than or equal to 174 ns in the region where the transmission speed of the ultrasonic wave is high in the layer L3, and sets the detection period of the cavity defect V23 to, for example, greater than or equal to 176 ns and less than or equal to 179 ns in the region where the transmission speed of the ultrasonic wave is low in the layer L3.

In addition, the processor 21 sets the detection period of the cavity defect V12 to, for example, greater than or equal to 176 ns and less than or equal to 179 ns in the region where the transmission speed of the ultrasonic wave is high in the layer L3, and sets the detection period of the cavity defect V12 to, for example, greater than or equal to 181 ns and less than or equal to 184 ns in the region where the transmission speed of the ultrasonic wave is low in the layer L3.

Thus, in the region where the transmission speed of the ultrasonic wave is high in the layer L3, the processor 21 determines that the reflected wave received at, for example, 172.5 ns is from the cavity defect V23, and determines that the reflected wave received at, for example, 177.5 ns is from the cavity defect V12.

In addition, in the region where the transmission speed of the ultrasonic wave is low in the layer L3, the processor 21 determines that the reflected wave received at, for example, 177.5 ns is from the cavity defect V23, and determines that the reflected wave received at, for example, 183 ns is from the cavity defect V12.

Although illustration is omitted in FIGS. 15A and 15B, data as illustrated in FIG. 15A is acquired also for the layer L2, and in the inspection of the semiconductor device in which the layers L1 to L3 have been bonded together, the detection periods of the individual cavity defects V12 and V23 can be set in consideration of the results for both the layers L2 and L3.

In addition, measurement of the transmission speed of the ultrasonic wave for each region of the layers L2 and L3 as illustrated in FIGS. 13A and 13B does not have to be performed every time. For example, one or a plurality of measurement targets may be extracted per lot, and an obtained result may be applied to the entire lot. Alternatively, measurement data of the transmission speed of the ultrasonic wave for identical products may be accumulated and learning is performed by the inspection apparatus 2, and setting of the detection periods of the individual cavity defects V12 and V23 may be automatically performed using a result of such learning.

In addition, when the inspection method of the third modification is performed, the cavity defect inspection may be performed in further consideration of the thickness of the support substrate SS or the like by the method described in any of the above-described embodiment and first and second modifications.

According to the inspection method of the third modification, the processor 21 estimates times required for reception of the respective reflected waves reflected by the individual cavity defects V12 and V23 in the region described above on the basis of a time from when an ultrasonic wave is emitted to a predetermined region by the probe 10 to when a reflected wave obtained by reflection of the ultrasonic wave is received by the probe 10, and sets each of the detection periods of the cavity defects V12 and V23 in the region described above on the basis of the times.

As a result, even in a case where the transmission speeds of the ultrasonic wave are different from each other for the respective plurality of regions of the layers L2 and L3, the inspection accuracy for the cavity defects V12 and V23 using the ultrasonic wave can be improved. In addition, since the detection time of each of the cavity defects V12 and V23 can be estimated with higher accuracy, it is possible to specify with higher accuracy which one of the cavity defects V12 and V23 the received reflected wave is caused by.

### Other Modifications

In the above-described embodiment and first to third modifications, as an example, the semiconductor device 1 has been described having a three-layer structure of the layer L1 including the peripheral circuits CBA and the layers L2 and L3 including the memory region MR, but the semiconductor device may include three or more layers including the memory region MR and the like. In this case, such a semiconductor device can be obtained by further repetition of bonding of layers corresponding to the layers L2, L3, and the like. In addition, also in this case, it is possible to perform inspection of a cavity defect in a bonding surface by any of the methods described in the above-described embodiment and first to third modifications every time each layer is bonded.

In addition, in the above-described embodiment and first to third modifications, the cavity defect inspection is performed on the three-dimensional nonvolatile memory such as the semiconductor device 1. However, the inspection method described in the above-described embodiment and first to third modifications can be applied not only to the above-described three-dimensional nonvolatile memory but also to various semiconductor devices and the like that can include cavity defects at different depth positions.

### Supplementary Note

Hereinafter, preferred aspects of the present invention will be supplementally noted.

### Supplemental Note 1

Provided is an inspection apparatus that performs detection of a cavity defect in a structure by emitting an ultrasonic wave to the structure,

the inspection apparatus including:

a probe that transmits and receives the ultrasonic wave; and

a processor that analyzes a reflected wave received by the probe, in which

the structure includes a first region and a second region disposed side by side along an extending direction of the structure,

the cavity defect to be a target of the detection includes at least any of:

a first cavity defect located at a first distance from a first end portion of the structure; and

a second cavity defect located at a second distance from the first end portion, the second distance being larger than the first distance, and

the processor:

estimates a first time and a second time required for reception of respective reflected waves reflected by the first and second cavity defects in the first region based on a time from when a first ultrasonic wave is emitted to the first region by the probe to when a first reflected wave obtained by reflection of the first ultrasonic wave is received by the probe, and sets each of a first detection period and a second detection period in the first region based on the first and second times; and

estimates a third time and a fourth time required for reception of respective reflected waves reflected by the first and second cavity defects in the second region based on a time from when a second ultrasonic wave is emitted to the second region by the probe to when a second reflected wave obtained by reflection of the second ultrasonic wave is received by the probe, and sets each of a third detection period and a fourth detection period in the second region based on the third and fourth times.

### Supplementary Note 2

In the inspection apparatus according to Supplementary Note 1,

the structure includes:

a first layer, a second layer, and a third layer sequentially disposed from a side of the first end portion of the structure;

a first bonding surface between the first layer and the second layer, the first bonding surface being located at the first distance from the first end portion; and

a second bonding surface between the second layer and the third layer, the second bonding layer being located at the second distance from the first end portion, and

the processor:

causes the probe to emit, to the first layer disposed above a substrate and before being bonded to the second layer, each of the first and second ultrasonic waves from a first layer side to a substrate side; and

causes the probe to receive each of the first and second reflected waves transmitted through the first layer and reflected by a lower surface of the substrate.

### Supplementary Note 3

Provided is an inspection method for performing detection of a cavity defect in a structure by emitting an ultrasonic wave to the structure, in which

the structure includes a first region and a second region disposed side by side along an extending direction of the structure,

the cavity defect to be a target of the detection includes at least any of:

a first cavity defect located at a first distance from a first end portion of the structure; and

a second cavity defect located at a second distance from the first end portion, the second distance being larger than the first distance, and

the detection of the cavity defect includes:

estimating a first time and a second time required for reception of respective reflected waves reflected by the first and second cavity defects in the first region based on a time from when emitting a first ultrasonic wave to the first region to when receiving a first reflected wave obtained by reflection of the first ultrasonic wave, and setting each of a first detection period and a second detection period in the first region based on the first and second times; and

estimating a third time and a fourth time required for reception of respective reflected waves reflected by the first and second cavity defects in the second region based on a time from when emitting a second ultrasonic wave to the second region to when receiving a second reflected wave obtained by reflection of the second ultrasonic wave, and setting each of a third detection period and a fourth detection period in the second region based on the third and fourth times.

### Supplementary Note 4

In the inspection method according to supplementary note 3,

the structure includes:

a first layer, a second layer, and a third layer sequentially disposed from a side of the first end portion of the structure;

a first bonding surface between the first layer and the second layer, the first bonding surface being located at the first distance from the first end portion; and

a second bonding surface between the second layer and the third layer, the second bonding surface being located at the second distance from the first end portion, and

the detection of the cavity defect includes:

emitting, to the first layer disposed above a substrate and before being bonded to the second layer, each of the first and second ultrasonic waves from a first layer side to a substrate side; and

receiving the first and second reflected waves transmitted through the first layer and reflected by a lower surface of the substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An inspection apparatus that detects a cavity defect in a structure by emitting an ultrasonic wave to a substrate including the structure on a first surface,
the inspection apparatus comprising:
a probe that transmits and receives the ultrasonic wave; and
a processor that analyzes a reflected wave received by the probe, wherein
the cavity defect includes at least any of:
a first cavity defect located at a first distance from a second surface on an opposite side from the first surface; and
a second cavity defect located at a second distance from the second surface, the second distance being larger than the first distance, and
the processor:
causes the probe to emit a first ultrasonic wave from a second surface side to a reference point;
causes the probe to receive a first reflected wave reflected at the reference point;
estimates a first time required for reception of a reflected wave reflected by the first cavity defect based on a time from when the first ultrasonic wave is emitted to the first reflected wave is received, and sets a first detection period based on the first time; and
estimates a second time required for reception of a reflected wave reflected by the second cavity defect based on a time from when the first ultrasonic wave is emitted to when the first reflected wave is received, and sets a second detection period based on the second time.

2. The inspection apparatus according to claim 1, wherein
the processor:
causes the probe to emit a second ultrasonic wave from the second surface side,
causes the probe to receive a second reflected wave obtained by reflection of the second ultrasonic wave,
determines that the second reflected wave is reflected from the first cavity defect in a case where a time from when the second ultrasonic wave is emitted to when the second reflected wave is received is within the first detection period, and
determines that the second reflected wave is reflected from the second cavity defect in a case where the time from when the second ultrasonic wave is emitted to when the second reflected wave is received is within the second detection period.

3. The inspection apparatus according to claim 1, wherein
the structure includes:
a first layer, a second layer, and a third layer sequentially disposed on the first surface;
a first bonding surface between the first layer and the second layer, the first bonding surface being located at the first distance from the second surface; and
a second bonding surface between the second layer and the third layer, the second bonding surface being located at the second distance from the second surface.

4. The inspection apparatus according to claim 3, wherein
the reference point is an edge portion of the substrate, the edge portion being out of the first and second bonding surfaces.

5. The inspection apparatus according to claim 4, wherein
the first layer extends to the edge portion of the substrate, and
the reference point is a front surface of the first layer extending to the edge of the substrate.

6. The inspection apparatus according to claim 4, wherein
the edge portion of the substrate includes a roll-off portion in which the substrate is thinner at a position closer to an outermost edge portion of the substrate,
the processor causes the probe to perform transmission of the first ultrasonic wave and reception of the first reflected wave with respect to a plurality of points, as the reference point of the roll-off portion, and
the first and second detection periods are:
set based on a point of the plurality of points, the point being a point for which the time from when the first ultrasonic wave is emitted to when the first reflected wave is received, is longest, or
set based on a time obtained by exponential approximation of the time from when the first ultrasonic wave is emitted to when the first reflected wave is received, at the plurality of points.

7. The inspection apparatus according to claim 3, wherein
the reference point is a reference void provided in any layer of the first to third layers and having a known depth position from the first surface.

8. The inspection apparatus according to claim 1, wherein
the structure includes a first region and a second region disposed side by side along the first surface, and
the processor:
adjusts the first and second detection periods in the first region based on a third time from when a third ultrasonic wave is emitted to the first region by the probe to when a third reflected wave obtained by reflection of the third ultrasonic wave is received by the probe, and
adjusts the first and second detection periods in the second region based on a fourth time from when a fourth ultrasonic wave is emitted to the second region by the probe to when a fourth reflected wave obtained by reflection of the fourth ultrasonic wave is received by the probe.

9. An inspection method for detecting a cavity defect in a structure by emitting an ultrasonic wave to a substrate including the structure on a first surface, wherein
the cavity defect includes at least any of:
a first cavity defect located at a first distance from a second surface on an opposite side from the first surface; and
a second cavity defect located at a second distance from the second surface, the second distance being larger than the first distance, and
detecting the cavity defect includes:
emitting a first ultrasonic wave from a second surface side to a reference point;
receiving a first reflected wave reflected at the reference point;
estimating a first time required for reception of a reflected wave reflected by the first cavity defect based on a time from when emitting the first ultrasonic wave to when receiving the first reflected wave, and setting a first detection period based on the first time; and
estimating a second time required for reception of a reflected wave reflected by the second cavity defect based on a time from when emitting the first ultrasonic wave to when receiving the first reflected wave, and setting a second detection period based on the second time.

10. The inspection method according to claim 9, wherein
detecting the cavity defect further includes:
emitting a second ultrasonic wave from the second surface side;
receiving a second reflected wave obtained by reflection of the second ultrasonic wave;
determining that the second reflected wave is reflected from the first cavity defect in a case where a time from when emitting the second ultrasonic wave to when receiving the second reflected wave is within the first detection period; and
determining that the second reflected wave is reflected from the second cavity defect in a case where the time from when emitting the second ultrasonic wave to when receiving the second reflected wave is within the second detection period.

11. The inspection method according to claim 9, wherein
the structure includes:
a first layer, a second layer, and a third layer sequentially disposed on the first surface;
a first bonding surface between the first layer and the second layer, the first bonding surface being located at the first distance from the second surface; and
a second bonding surface between the second layer and the third layer, the second bonding surface being located at the second distance from the second surface, and
emitting the first ultrasonic wave to the reference point includes:
emitting the first ultrasonic wave to an edge portion, as the reference point, of the substrate, the edge portion being out of the first and second bonding surfaces.

12. The inspection method according to claim 11, wherein
the first layer extends to the edge portion of the substrate, and
emitting the first ultrasonic wave to the reference point includes:
emitting the first ultrasonic wave to a front surface, as the reference point, of the first layer extending to the edge portion of the substrate.

13. The inspection method according to claim 11, wherein
the edge portion of the substrate includes a roll-off portion in which the substrate is thinner at a position closer to an outermost edge portion of the substrate,
emitting the first ultrasonic wave to the reference point includes:
performing transmission of the first ultrasonic wave and reception of the first reflected wave with respect to a plurality of points, as the reference point of the roll-off portion, and
the first and second detection periods are:
set based on a point of the plurality of points, the point being a point for which the time from when emitting the first ultrasonic wave to when receiving the first reflected wave is longest, or
set based on a time obtained by exponential approximation of the time from when emitting the first ultrasonic wave to when receiving the first reflected wave, at the plurality of points.

14. The inspection method according to claim 9, wherein
the structure includes a first region and a second region disposed side by side along the first surface, and
detecting the cavity defect further includes:
adjusting the first and second detection periods in the first region based on a third time from when emitting a third ultrasonic wave to the first region to when receiving a third reflected wave obtained by reflection of the third ultrasonic wave; and
adjusting the first and second detection periods in the second region based on a fourth time from when emitting a fourth ultrasonic wave to the second region to when receiving a fourth reflected wave obtained by reflection of the fourth ultrasonic wave.

15. A method for manufacturing a semiconductor device including an inspection method for detecting a cavity defect in a structure by emitting an ultrasonic wave to a substrate including the structure on a first surface, wherein
the cavity defect includes at least any of:
a first cavity defect located at a first distance from a second surface on an opposite side from the first surface; and
a second cavity defect located at a second distance from the second surface, the second distance being larger than the first distance, and
detecting the cavity defect includes:
emitting a first ultrasonic wave from a second surface side to a reference point;
receiving a first reflected wave reflected at the reference point;
estimating a first time required for reception of a reflected wave reflected by the first cavity defect based on a time from when emitting the first ultrasonic wave to when receiving the first reflected wave, and setting a first detection period based on the first time; and
estimating a second time required for reception of a reflected wave reflected by the second cavity defect based on a time from when emitting the first ultrasonic wave to when receiving the first reflected wave, and setting a second detection period based on the second time.

16. A method for manufacturing a semiconductor device including an inspection method for detecting a cavity defect in a structure by emitting an ultrasonic wave to the structure, wherein
the structure includes a first region and a second region disposed side by side along an extending direction of the structure,
the cavity defect includes at least any of:
a first cavity defect located at a first distance from a first end portion of the structure; and
a second cavity defect located at a second distance from the first end portion, the second distance being larger than the first distance, and
detecting the cavity defect includes:
estimating a first time and a second time required for reception of respective reflected waves reflected by the first and second cavity defects in the first region based on a time from when emitting a first ultrasonic wave to the first region to when receiving a first reflected wave obtained by reflection of the first ultrasonic wave, and setting each of a first detection period and a second detection period in the first region based on the first and second times; and
estimating a third time and a fourth time required for reception of respective reflected waves reflected by the first and second cavity defects in the second region based on a time from when emitting a second ultrasonic wave to the second region to when receiving a second reflected wave obtained by reflection of the second ultrasonic wave, and setting each of a third detection period and a fourth detection period in the second region based on the third and fourth times.
